(19) United States
(12) Patent Application Publication
(10) Pub. No.: US 2007/0277875 A1
(43) Pub. Date: Dec. 6, 2007

(54) Thin film photovoltaic structure

(76) Inventors: Kishor Purushottam Gadkaree, Big Flats, NY (US); David Francis Dawson-Elli, Elmira, NY (US); Robin Merchant Walton, Painted Post, NY (US)

Correspondence Address: CORNING INCORPORATED, SP-TI-3-1, CORNING, NY, 14831, US

(21) Appl. No.: 11/511,041

(22) Filed: Aug. 28, 2006

Related U.S. Application Data
(60) Provisional application No. 60/810,061, filed on May 31, 2006.

(51) Int. Cl. H01L 31/00

(52) U.S. Cl. 136/256

(57) ABSTRACT

Photovoltaic devices include an insulator structure bonded to an exfoliation layer, preferably of a substantially single-crystal donor semiconductor wafer, and at least one photovoltaic device layer, such as a conductive layer. In a preferred embodiment, a device may include a conductive layer adjacent to the insulator substrate and integral to the exfoliation layer, near the side that faces the insulator substrate, such as between the insulator substrate and the exfoliation layer. In a further preferred embodiment, a device may include a plurality of photovoltaic device layers distal to the insulator substrate and in or on the exfoliation layer, preferably having been epitaxially grown on the exfoliation layer after the exfoliation layer has been anodically bonded to the insulator substrate by means of electrolysis.

### CROSS-REFERENCE TO RELATED APPLICATIONS

The present invention claims the benefit of the filing date of the prior-filed U.S. Provisional Patent Application No. 60/810061 filed on May 31, 2006 by David Francis Dawson-Elli et al. and entitled “SINGLE CRYSTAL THIN FILM PHOTOVOLTAIC STRUCTURE,” the content of which is relied upon and incorporated herein by reference in its entirety.

### BACKGROUND

1. Field of Invention

The present invention relates to the systems, methods and products of manufacture of a thin film photovoltaic structure, preferably having a substantially single crystal thin film, using improved processes, including in particular transferring photovoltaic structure foundations or partially completed photovoltaic structures to insulator substrates and anodic bonding to the insulator substrates.

2. Description of Related Art

### Overview of Photovoltaics

Photovoltaic structures (PVS) are a specialized form of semiconductor structure that converts photons into electricity. Fundamentally, the device needs to fulfill only two functions: photogeneration of charge carriers (electrons and holes) in a light-absorbing material, and separation of the charge carriers to a conductive contact that will transmit the electricity. This conversion is called the photovoltaic (PV) effect and used in solar cells, which convert light energy into electrical energy, and the field of research related to solar cells is known as photovoltaics. Some PVS are semiconductor-on-insulator (SOI) structures.

Photovoltaic cells commonly are configured as a large-area p-n junction (“p” denoting positive, “n” denoting negative). A-p-n junction functionally is a layer of n-type silicon in direct contact with a layer of p-type silicon. Alternatively, a p-i-n configuration may be preferable, where “i” here refers to “intrinsic” semiconductor separating the p-type and n-type layers, as a buffer. In practice, a p-n junction of a silicon solar cell is made by diffusing an n-type dopant into one side of a p-type wafer (or vice versus). With a piece of p-type silicon in intimate contact with a piece of n-type silicon, a diffusion of electrons occurs from the region of high electron concentration (the n-type side of the junction) into the region of low electron concentration (p-type side of the junction). When the electrons diffuse across the p-n junction, they recombine with holes on the p-type side.

This diffusion creates an electric field by the imbalance of charge immediately on either side of the junction. The electric field established across the p-n junction creates a diode that promotes current to flow in only one direction across the junction. Electrons may pass from the n-type side into the p-type side, and holes may pass from the p-type side to the n-type side. This region where electrons have diffused across the junction is called the depletion region because it no longer contains any mobile charge carriers. It is also known as the “space charge region”.

To connect the photovoltaic cell to a load, ohmic metal-semiconductor contacts are made to both the n-type and p-type sides of the solar cell, and the electrodes connected to an external load. Electrons that are created on the n-type side, or have been “collected” by the junction and swept onto the n-type side, may travel through the wire, power the load, and continue through the wire until they reach the p-type semiconductor-metal contact. Here, they recombine with a hole that was either created as an electron-hole pair on the p-type side of the solar cell, or swept across the junction from the n-type side after being created there.

### Photovoltaic Structures

To date, the semiconductor material most commonly used in such semiconductor-on-insulator (SOI) structures has been silicon. Such structures have been referred to in the literature as silicon-on-insulator structures and the abbreviation “SOI” has been applied to such structures as well. SOI technology is becoming increasingly important not only for solar cells, but also for high performance thin film transistors, and displays, such as active matrix displays. SOI structures may include a thin layer of substantially single-crystal silicon (generally 0.05-0.3 microns (50-300 nm) in thickness but, in some cases, as thick as 5 microns (5000 nm) on an insulating material.

Photovoltaic structures share many of the same processing and manufacturing techniques with other semiconductor devices such as computer and memory chips. However, the stringent requirements for cleanliness and quality-control of semiconductor fabrication are a little more relaxed for solar cells. Solar cell technology typically uses bulk crystalline silicon (single crystal, crystal-Si, and cast polycrystal, p-Si) and thin film Si, achieved by deposition (CVD, LPE, PECVD, etc.) of a thin film of Si onto a substrate. The thin film may be amorphous (e.g., a-Si) or polycrystalline (e.g., p-Si, Cu—In—Se2, CdTe).

The primary issues with the use of bulk Si are the cost and supply of so-called solar grade silicon and its utilization. Most large-scale commercial solar cell factories today make screen printed poly-crystalline silicon solar cells. With a typical bulk crystal-Si or p-Si solar cell of 200 microns thick, the kerf loss from cutting wafers from boules or cast ingots is approximately 30%, significantly contributing to the overall cost. Single crystalline wafers which are used in the semiconductor industry can be made in to excellent high efficiency solar cells, but they are generally considered to be too expensive for large-scale mass production.

Thus, the use of thin films is of particular interest from a cost perspective. Thin-film solar cells use less than 1% of the raw material (silicon or other light absorbers) compared to wafer based solar cells, leading to a significant price drop per kWh. One particularly promising technology is crystalline silicon thin films on glass substrates. This technology makes use of the advantages of crystalline silicon as a solar cell material, with the cost savings of using a thin-film approach.

The challenges of thin film use vary depending on the particular technology. The various thin-film technologies currently being developed reduce the amount (or mass) of light absorbing material required in creating a solar cell. This can lead to reduced processing costs from that of bulk materials (in the case of silicon thin films) but also tends to reduce energy conversion efficiency, although many multi-layer thin films have efficiencies above those of bulk silicon wafers. For a-Si, efficiency of energy conversion is a major issue, with a common range of 10%-13%. By comparison, crystalline Si attains higher efficiencies, such as 15%.

Referring to FIGS. 1, 2, and 3, block diagrams illustrate a single-junction, a dual-junction, and a triple-junction photovoitaic structure, respectively. The germanium substrate illustrated is a single crystal Ge wafer. Also provided are the progressions of the historical efficiencies of each While the efficiency of each has risen 1%-3.5% over the past few years, the greater increases in efficiency have come with the addition of junctions, with each additional junction adding about 4.5%. This benefit of the additional junctions is due to the ability of the PVS device to absorb light across different band gaps and convert it to electricity, making use of more of the available light.

Each type of semiconductor will have a characteristic band gap energy which, loosely speaking, causes it to absorb “light” most efficiently at a certain “color”, or more precisely, to absorb electromagnetic radiation over a portion of the spectrum. The semiconductors are carefully chosen to absorb nearly the entire solar spectrum, thus generating electricity from as much of the solar energy as possible. GaAs multijunction devices are the most efficient solar cells to date, reaching as high as 39% efficiency. They are also some of the most expensive cells per unit area.

Multijunction solar cells consist of layers of semiconductors with decreasing bandgaps. The top layers absorb higher-energy photons, while transmitting lower-energy photons that can then be absorbed by lower layers of the cell. It is desirable, in terms of the full exploitation of materials and light energy, to “current match” these layers. Different materials have different rates of photon absorption, or absorptivity. The thickness of each layer of material is adjusted in a way that best ensures that each layer of the series-connected device generates the same amount of electrical current.

Defects in the crystal structure of the semiconductor can impede performance considerably. Significant defect reduction is achieved by “lattice matching” semiconductor layers to create similar crystal structures throughout all layers of the cell. It is possible to stack multijunction solar cell layers mechanically, but it is generally accepted as more practical and economical to grow these layers monolithically, typically by metal-organic chemical vapor deposition.

A solar cell's energy conversion efficiency (η, “eta”), is the percentage of power converted (from absorbed light to electrical energy) and collected, when a solar-cell is connected to an electrical circuit. This term is calculated using the ratio of Pₘ, divided by the input light irradiance under “standard” test conditions (E, in W/m²) and the surface area of the solar cell (A_{c} in m²). Written mathematically, η=Pₘ/(E*A_{c}).

At solar noon on a clear March or September equinox-day, the solar radiation at the equator is about 1000 W/m². Hence, the “standard” solar radiation (known as the “air mass 1.5 spectrum”) has a power density of 1000 watts per square meter. Thus, a 12% efficiency solar cell having 1 m² of surface area in full sunlight at solar noon at the equator during either the March or September equinox will produce approximately 120 watts of peak power.

Silicon solar cell efficiencies vary from 6% for amorphous silicon-based solar cells to 30% or higher with multiple-junction research lab cells. Solar cell energy conversion efficiencies for commercially available multicrystalline silicon (mc-Si) solar cells are around 12%. Though, the highest efficiency cells often are not the most economical—for example a 30% efficient multijunction cell based on exotic materials such as gallium arsenide or indium selenide and produced in low volume might well cost one hundred times as much as an 8% efficient amorphous silicon cell in mass production, while only delivering a little under four times the electrical power.

Thin film Si PVS technology also has issues, inasmuch as the process temperatures used in the literature are near the melting point of Si, so there are considerable constraints on the substrate (purity, expansion coefficient, ability to contact the cell, etc.). In addition to Si, thin film structures may be made from other materials, including CIGS, CIS, CdTe, and GaAs, each of which has its own issues.

Cost is an issue for CIGS PVS, made of multi-layered thin-film composites. The abbreviation stands for copper-indium-gallium-selenide. Unlike the basic silicon solar cell, which can be modeled as a simple p-n junction, these cells are best described by a more complex heterojunction model. The best efficiency of a CIGS thin-film solar cell as of December 2005 was 19.5%. Higher efficiencies (around 30%) can be obtained by using optics to concentrate the incident light. As of 2006, one of the best conversion efficiencies for flexible CIGS cells on polyimide is 14.1% by Tiwari, et al., at the ETH, Switzerland.

Manufacturability is an issue for both CIS and CdTe PVS, which have difficulties achieving uniformity of performance over large areas. CIS is an abbreviation for copper-indium-selenide, such as general chalcogenide films of Cu(InₓGa₁₋ₓ)(SeₓS₁₋ₓ)₂. While CIS films can achieve 11% efficiency, their manufacturing costs are high at present. Efforts are underway to find more cost effective production processes. On the other hand, cadmium telluride, CdTe, is an efficient light absorbent material for thin-film solar cells. However, Cd is regarded as a toxic heavy metal, reducing the incentive for development.

Cost also is an issue for high-efficiency gallium arsenide (GaAs) multifunction cells, which have been developed for special applications such as satellites and space exploration that require high-performance. These multifunction cells consist of multiple thin films produced using molecular beam epitaxy. A triple-junction cell, for example, may consist of the semiconductors: GaAs, Ge, and GaInP₂. Factoring into the cost is the formation of ohmic contacts, discussed more below, to such compound semiconductors, which is considerably more difficult than with silicon. For example, GaAs surfaces tend to lose arsenic, and the trend towards As loss can be exacerbated considerably by the deposition of metal. In addition, the volatility of As limits the amount of post-deposition annealing that GaAs devices will tolerate. One solution for GaAs and other compound semiconductors is to deposit a low-bandgap alloy contact layer as opposed to a heavily doped layer. For example, GaAs itself has a smaller bandgap than AlGaAs and so a layer of GaAs near its surface can promote ohmic behavior.

In general, the technology of ohmic contacts for III-V and II-VI semiconductors is much less developed than for Si, as can be seen by the number of commonly used ohmic contact materials listed below for various semiconductor materials:

| Semiconductor | |
|---|---|
| Material | Ohmic Contact Materials |
| Si | Al, Al—Si, TiSi₂, TiN, W, MoSi₂, PtSi, CoSi₂, WSi₂ |
| Ge | In, AuGa, AuSb |
| GaAs | AuGe, PdGe, Ti/Pt/Au |
| GaN | Ti/Al/Ti/Au, Pd/Au |
| InSb | In |
| ZnO | InSnO₂, Al |
| CuIn₁₋ₓGaₓSe₂ | Mo, InSnO₂ |
| HgCdTe | In |

### Photovoltaic Structure Manufacture

From a manufacturing perspective, for example, poly-crystalline silicon wafers for photovoltaic structures are made by wire-sawing block-cast silicon ingots into very thin (250 to 350 micrometer) slices or wafers. The wafers are usually lightly p-type doped. To make a solar cell from the wafer, a surface diffusion of n-type dopants is performed on the front side of the wafer. This forms a p-n junction a few hundred nanometers below the surface.

Antireflection coatings, which increase the amount of light coupled into the solar cell, are typically applied next. Over the past decade, silicon nitride has gradually replaced titanium dioxide as the antireflection coating of choice because of its excellent surface passivation qualities (i.e., it prevents carrier recombination at the surface of the solar cell). It is typically applied in a layer several hundred nanometers thick using plasma-enhanced chemical vapor deposition (PECVD). Some solar cells have textured front surfaces that, like antireflection coatings, serve to increase the amount of light coupled into the cell. Such surfaces usually may be formed on only single-crystal silicon, though in recent years methods of forming them on multicrystalline silicon have been developed.

The wafer is then metallized, whereby a full area metal contact is made on the back surface, and a grid-like metal contact made up of fine “fingers” and larger “busbars” is screen-printed onto the front surface using a silver paste. The rear contact is also formed by screen-printing a metal paste, typically aluminum. Usually this contact covers the entire rear side of the cell, though in some cell designs it is printed in a grid pattern. The metal electrodes will then require some kind of heat treatment or “sintering” to make ohmic contact with the silicon, i.e., so that the current-voltage (I-V) curve of the device is linear and symmetric.

Modern ohmic contacts to silicon, such as titanium or tungsten disilicide, are usually silicides made by CVD. A silicide is a combination of silicon with more electropositive elements. An exemplary silicide might include a high temperature metal, such as tungsten, titanium, cobalt, or nickel, alloyed with silicon. Contacts are often made by first depositing the transition metal and second forming the silicide by annealing, with the result that the silicide may be non-stoichiometric. Silicide contacts can also be deposited by direct sputtering of the compound or by ion implantation of the transition metal followed by annealing.

Aluminum is another important contact metal for silicon that can be used with either the n-type or p-type semiconductor. As with other reactive metals, Al contributes to contact formation by consuming the oxygen in the native oxide. Silicides have largely replaced Al in part because the more refractory materials are less prone to diffuse into unintended areas especially during subsequent high-temperature processing.

After the metal contacts are made, the solar cells are interconnected in series (and/or parallel) by flat wires or metal ribbons, and assembled into modules or “solar panels”. Solar panels have a sheet of tempered glass on the front, and a polymer encapsulation on the back. Tempered glass typically is incompatible for use with amorphous silicon cells because of the high temperatures during the deposition process.

As mentioned above, manufacturing photovoltaic cells using wire-sawing bulk Si results in significant waste of prepared Si. Given that the strict controls necessary for manufacturing semiconductors for use in microelectronics are less applicable to manufacturing semiconductors for use in photovoltaic structures, many of the improvements to microelectronic manufacturing may be applied readily, with some modification, to photovoltaic cell manufacturing. It is therefore desirable to identify novel modified semiconductor manufacturing techniques applicable to photovoltaic structures that provide advantages specific to photovoltaic cells, such as increased efficiency and reduced cost.

### Advanced Photovoltaic Structures

There is a need for mechanically strong, large area, less expensive solar cells. GaAs based solar cells are a route to improved conversion efficiencies and improved outdoor reliability. GaAs which has a band gap of 1.42 eV which is close to the optimum value (1.5 eV) of band gap energy for solar energy conversion. Unlike silicon cells, GaAs cells are relatively insensitive to heat. Another significant advantage of gallium arsenide and its alloys as PV cell materials is that it is amenable to a wide range of designs. Most notably are the high efficiency multijunction solar cells which utilize thin films of GaAs or other III-V based materials such as GaInP₂ and GaInAs on bulk Ge single crystal substrates. GaAs-based multijunction solar cells have- the highest demonstrated efficiencies of over 37%. The configuration of the record-efficiency, three-junction device is Ga_{0.44}In_{0.56}P/Ga_{0.92}In_{0.08}As/Ge. Germanium substrates have been used for these cells as GaAs and Ge are closely matched in lattice spacing and thermal expansion.

The high cost of Ge and GaAs substrates has limited the use of these high efficiency multijunction cells to concentrator systems for space power applications. In a typical concentrator system, the concentrator cell is about 0.25 cm² in area and can produce ample power under high concentrations. In such a configuration, GaAs cells can be competitive, assuming module efficiencies between 25% and 30% and an overall reduction of system costs. Optional approaches for lowering the cost of GaAs devices are: fabricating GaAs cells on cheaper substrates; growing GaAs cells on a removable, reusable GaAs substrate; and making GaAs thin films similar to those of copper indium diselenide. For GaAs solar cells the active layers are only a few micrometers thick, but they must be grown on single crystal substrates. In the final cell, essentially more than 95% of the material is not needed. Efforts to fabricate thin film GaAs cells on cheaper substrates are described below.

Several research and development efforts exist to identify innovative ways to fabricate high efficiency GaAs based cells on silicon substrates. One approach involves epitaxial deposition of high-quality GaAs layers onto Si substrates having a crystalline Ge layer. This approach is appealing in view of the lower price and weight of Si compared to GaAs and Ge. High performance p+/n GaAs solar cells also have been grown and processed on compositionally graded Ge—Si₁₋ₓGeₓSi (termed a “virtual” Ge) substrates. For these cells, total area efficiencies of 18.1% under the AM1.5G spectrum were measured for 0.0444 cm² solar cells.

Another potentially lower cost “virtual” Ge substrate that has been investigated for photovoltaic applications is a Ge/Si heterostructure formed by wafer-bonding and layer-transfer to a Si substrate of a thin crystalline Ge layer formed by H-induced exfoliation. For instance, researchers have used H-induced layer-exfoliation to transfer 700 nm thick, single crystal Ge films to Si substrates. Triple junction solar cell structures were grown on these Ge/Si heterostructure templates by MOCVD. Deposition of a 250 nm-thick Ge buffer layer grown by MBE was done to smooth the exfoliated Ge surface and to improve optical and electrical properties.

A further recently reported method for obtaining crystalline Ge on silicon substrates, such as for epitaxial deposition of high quality GaAs thereon, combines two existing and cheap technologies: porosification of the Si substrate, and subsequent Ge deposition using CSVT (Close Spaced Vapor Transport). Although growth of III-V solar cells on these Ge-capped silicon substrates has been demonstrated, these cells usually show inferior crystal quality compared to growth on GaAs or Ge substrates.

Substrates lower in cost than crystalline silicon including glass and ceramic alumina are being investigated for III-V compound semiconductor solar cell applications. In one example, fused silica and ceramic alumina coated with thick Ge films are used as Ge-coated surrogate substrates for epitaxial growth of high-performance GaAs/InGaP solar cells. Germanium films (2-5 μm) are deposited on thermal-expansion matched polycrystalline alumina (p-Al₂O₃). The Ge films are subsequently capped with various metal and oxide films and then re-crystallized with rapid thermal processing. Average grain sizes greater than 1 mm are achieved. Epitaxial layers of GaAs are grown on these large grain (>1 mm) thin (˜2 μm) Ge layers using a CSVT technique. These GaAs/Ge/ceramic structures have been proposed as a starting point for tandem junction devices.

Having III-V semiconductor thin-film solar cells directly on a cover glass is very advantageous in that it reduces the weight of the substrate and reduces integration process costs. The solar cell practically may take a configuration with incident solar radiation upon the cover glass substrate side.

For example, thin film p-n GaAs solar cells have been formed on glass substrates by epitaxial liftoff. The -structure consists of an n-GaAs active region sandwiched between In_{0.49}Ga_{0.21}Al_{0.3}P and In_{0.49}Ga_{0.51}P window/passivation layers and capped by a p+-GaAs contact layer. The entire structure is grown by MOCVD on top of a 500 Å thick sacrificial layer of AlAs which is subsequently etched to release the device from its substrate. After device fabrication, the sample was covered with black wax and lifted off of its substrate by selectively etching the AlAs layer in HF acid solution, and attached to a glass substrate with UV-curing polyurethane.

Finally, researchers have investigated deposited polycrystalline thin films on glass substrates- for space solar cell application. The crystal quality limits the performance of the III-V solar cells with polycrystalline films. To wit, none of the aforementioned structures on low cost, glass substrates have led to GaAs cells with high efficiencies (>30%). Hence, a process and product based on a low cost and transparent glass substrate are desired that overcome the issues associated with prior art.

### SOI Manufacturing Techniques

Drawing from the microelectronic semiconductor world and for ease of presentation, the following discussion will at times be in terms of semiconductor-on-insulator (SOI) structures. The references to this particular type of SOI structure are made to facilitate the explanation of the invention and are not intended to, and should not be interpreted as, limiting the invention's scope in any way. The SOI abbreviation is used herein to refer to semiconductor-on-insulator structures in general, including, but not limited to, silicon-on-insulator structures, such as silicon-on-glass (SiOG) structures. Similarly, the SiOG abbreviation is used to refer to semiconductor-on-glass structures in general, including, but not limited to, silicon-on-glass structures. The SiOG nomenclature is also intended to include semiconductor-on-glass-ceramic structures, including, but not limited to, silicon-on-glass-ceramic structures. The abbreviation SOI encompasses SiOG structures.

Various ways of obtaining SOI-structure wafers include (1) epitaxial growth of silicon (Si) on lattice-matched substrates; (2) bonding of a single-crystal silicon wafer to another silicon wafer on which an oxide layer of SiO₂ has been grown, followed by polishing or etching of the top wafer down to, for example, a 0.05 to 0.3 micron (50-300 nm) layer of single-crystal silicon; and (3) ion-implantation methods, in which either hydrogen or oxygen ions are implanted, either to form a buried oxide layer in the silicon wafer topped by Si, in the case of oxygen ion implantation, or to separate (exfoliate) a thin Si layer from one silicon wafer for bonding to another Si wafer with an oxide layer, as in the case of hydrogen ion implantation.

The former two methods, epitaxial growth and wafer-wafer bonding, have not resulted in satisfactory structures in terms of cost and/or bond strength and durability. The latter method involving ion implantation has received some attention, and, in particular, hydrogen ion implantation has been considered advantageous because the implantation energies required are typically less than 50% of that of oxygen ion implants and the dosage required is two orders of magnitude lower.

### Thin Film Single Crystal SOI Techniques

U.S. Pat. No. 5,374,564 discloses a process to obtain a single-crystal silicon film on a substrate using a thermal process. A silicon wafer having a planar face is subject to the following steps: (i) implantation by bombardment of a face of the silicon wafer by means of ions creating a layer of gaseous micro-bubbles defining a lower region of the silicon wafer and an upper region constituting a thin silicon film; (ii) contacting the planar face of the silicon wafer with a rigid material layer (such as an insulating oxide material); and (iii) a third stage of heat treating the assembly of the silicon wafer and the insulating material at a temperature above that at which the ion bombardment was carried out. The third stage employs temperatures sufficient to bond the thin silicon film and the insulating material together, to create a pressure effect in the micro-bubbles, and to cause a separation between the thin silicon film and the remaining mass of the silicon wafer. (Due to the high temperature steps, this process is not compatible with lower-cost glass or glass-ceramic substrates.)

U.S. Patent Application Publication No. 2004/0229444 discloses a process that produces an SOI structure, the content of which is incorporated herein by reference in its entirety. According to an one or more embodiments of Application 2004/0229444, the steps include: (i) exposing a silicon wafer surface to hydrogen ion implantation to create a bonding surface; (ii) bringing the bonding surface of the wafer into contact with a glass substrate; (iii) applying pressure, temperature and voltage to the wafer and the glass substrate to facilitate bonding therebetween; and (iv) cooling the structure to a common temperature to facilitate separation of the glass substrate and a thin layer of silicon from the silicon wafer.

More generally speaking, in view of the related art, a donor substrate and a recipient substrate are provided, wherein the donor substrate comprises a semiconductor material (e.g., Si, Ge, GaAs, etc.) and the recipient substrate comprises an insulator material (e.g., oxide glass or oxide glass-ceramic). The donor substrate includes a first donor external surface and a second donor external surface, the first donor external surface opposing the second donor external surface and comprising a first bonding surface for bonding with the recipient substrate. The recipient substrate includes a first recipient external surface and a second recipient external surface, the first recipient external surface opposing the second recipient external surface and comprising a second bonding-surface for bonding to the donor substrate.

A plurality of ions are implanted through the first donor external surface to create an ion implantation zone of the donor substrate at an implantation depth below the first donor external surface, after which the first and second bonding surfaces are brought into contact. For a period of time sufficient for the donor and recipient substrates to bond to one another at the first and second bonding surfaces, simultaneously: (1) forces are applied to the donor substrate and/or the recipient substrate such that the first and second bonding surfaces are pressed into contact; (2) the donor and recipient substrates are subjected to an electric field being generally directed from the second recipient external surface to the second donor external surface; and (3) the donor and recipient substrates are heated differentially, so that the second donor external surface and the second recipient external surface have average temperatures T1 and T2, respectively.

Temperatures T1 and T2 are selected such that upon cooling to a common temperature, the donor and recipient substrates undergo differential contraction to thereby weaken the donor substrate at the ion implantation zone. Thereafter, the bonded donor and recipient substrates are cooled, splitting the donor substrate at the ion implantation zone. The insulator material desirably is chosen to comprise positive ions that move during bonding within the recipient substrate in a direction away from the second bonding surface and towards the second recipient external surface.

The resulting SOI structure just after exfoliation might exhibit excessive surface roughness (e.g., about 10 nm or greater), excessive silicon layer thickness (even though the layer is considered “thin”), unwanted hydrogen ions, and implantation damage to the silicon crystal layer (e.g., due to the formation of an amorphized silicon layer). Because one of the primary advantages of the SiOG material lies in the single-crystal nature of the film, this lattice damage must be healed or removed. Second, the hydrogen ions from the implant are not removed fully during the bonding process, and because the hydrogen atoms may be electrically active, they should be eliminated from the film to insure stable device operation. Lastly, the act of cleaving the silicon layer- leaves a rough surface, which is known to cause poor transistor operation, so the surface roughness should be reduced to preferably less than 1 nm R_{A} prior to device fabrication.

These issues may be treated separately. For example, a thick (500 nm) silicon film is transferred initially to the glass. The top 420 nm then may be removed by polishing to restore the surface finish and eliminate the top damaged region of silicon. The remaining silicon film then may be annealed in a furnace for up to 8 hours at 600 degrees C to diffuse out the residual hydrogen.

Chemical mechanical polishing (CMP) may be used also to process the SOI structure after the thin silicon film has been exfoliated from the silicon material wafer. Disadvantageously, however, the CMP process does not remove material unifornly across the surface of the thin silicon film during polishing. Typical surface non-uniformities (standard deviation/mean removal thickness) are in the 3-5% range for semiconductor films. As more of the silicon film's thickness is removed, the variation in the film thickness correspondingly worsens.

The above shortcoming of the CMP process is especially a problem for some silicon-on-glass applications because, in some cases, as much as about 300-400 nm of material needs to be removed to obtain a desired silicon film thickness. For example, in thin film transistor (TFT) fabrication processes, a silicon film thickness in the 100 nm range or less may be desired.

Another problem with the CMP process is that it exhibits particularly poor results when rectangular SOI structures (e.g., those having sharp corners) are polished. Indeed, the aforementioned surface non-uniformities are amplified at the corners of the SOI structure compared with those at the center thereof. Still further, when large SOI structures are contemplated (e.g., for photovoltaic applications), the resulting rectangular SOI structures are too large for typical CMP equipment (which are usually designed for the 300 mm standard wafer size). Cost is also an important consideration for commercial applications of SOI structures. The CMP process, however, is costly both in terms of time and money. The cost problem may be significantly exacerbated if non-conventional CMP machines are required to accommodate large SOI structure sizes.

In addition to CMP processing, a furnace anneal (FA) may be used to remove any residual hydrogen. However, high temperature anneals are not compatible with lower-cost glass or glass-ceramic substrates. Lower temperature anneals (less than 700 degrees C) require long times to remove residual hydrogen, and are not efficient in repairing crystal damage caused by implantation. Furthermore, both CMP and furnace annealing increase the cost and lower the yield of manufacturing.

In contrast to microelectronic applications of SOI structures, photovoltaic structures are more tolerant of such defects, although such defects nonetheless adversely may affect performance of the photovoltaic cell. While such finishing techniques as CMP and FA may improve surface characteristics, the defect-tolerance of photovoltaic structures may make them cost-prohibitive. It would therefore be desirable to incorporate the advantages of SOI structure manufacturing advances with the requirements of the photovoltaic structure manufacturing, while minimizing the disadvantages of the associated SOI structure manufacturing advances.

### SUMMARY OF THE INVENTION

In accordance with one or more embodiments of the present invention, systems, methods and apparatus of forming a photovoltaic device include creating an exfoliation layer and transferring it to an insulator structure. The exfoliation layer may be created from a donor semiconductor wafer. The donor semiconductor wafer and the exfoliation layer preferably may comprise substantially single crystal semiconductor material. The exfoliation layer preferably may include one or more photovoltaic device layers, such as a conductive layer, created prior to transfer to the insulator substrate. Transferring the exfoliation layer preferably may include forming by electrolysis an anodic bond between the exfoliation layer and the insulator substrate and then separating the exfoliation layer from the donor semiconductor wafer using thermo-mechanical stress. One or more photovoltaic device layers also may be created in, on or above the exfoliation layer after the exfoliation layer has been transferred to the insulator substrate. One or more finishing processes may be performed before or after transferring the exfoliation layer, and performance of a finishing process may create a photovoltaic device layer.

In accordance with one or more embodiments of the present invention, systems, methods and apparatus of forming a photovoltaic semiconductor-on-insulator structure, include creating a photovoltaic structure foundation on a donor semiconductor wafer, transferring the photovoltaic structure foundation to an insulator substrate, and depositing a plurality of photovoltaic structure layers on the PV foundation. Transferring may include anodic bonding of the photovoltaic structure foundation to the insulator structure, and separating the photovoltaic structure foundation from the donor semiconductor wafer.

In accordance with one or more embodiments of the present invention, systems, methods and apparatus of forming a photovoltaic semiconductor-on-insulator structure, include creating a partially completed photovoltaic cell on a donor semiconductor wafer, and transferring the partially completed photovoltaic structure to an insulator substrate. Transferring may include anodic bonding of the partially completed photovoltaic cell to the insulator structure, and separating the partially completed photovoltaic cell from the donor semiconductor wafer.

In accordance with one or more embodiments of the present invention, systems, methods and apparatus of forming a photovoltaic device include: subjecting a donor semiconductor wafer to an ion implantation process to create an exfoliation layer in the donor semiconductor wafer; bonding the exfoliation layer to an insulator substrate; separating the exfoliation layer from the donor semiconductor wafer, the exfoliation layer to serve as a photovoltaic structure foundation; and creating a plurality of photovoltaic structure layers on the photovoltaic structure foundation.

In accordance with one or more embodiments of the present invention, systems, methods and apparatus of forming a photovoltaic device include: subjecting a donor semiconductor wafer to an ion implantation process to create an exfoliation layer in the donor semiconductor wafer; creating a partially completed photovoltaic cell on the exfoliation layer; bonding the exfoliation layer to an insulator substrate; separating the exfoliation layer having the partially completed photovoltaic cell from the donor semiconductor wafer, thereby exposing at least one cleaved surface; and subjecting the at least one cleaved surface to a finishing process.

In accordance with one or more embodiments of the present invention, systems, methods and apparatus of forming a photovoltaic device include: creating a partially completed photovoltaic cell on a donor semiconductor wafer; subjecting the partially completed photovoltaic cell and the prepared donor surface of the donor semiconductor wafer to an ion implantation process to create an exfoliation layer in the donor semiconductor wafer; bonding the exfoliation layer to an insulator substrate; separating the exfoliation layer having the partially completed photovoltaic cell from the donor semiconductor wafer, thereby exposing at least one cleaved surface; and subjecting the at least one cleaved surface to a finishing process.

In one or more embodiments, the step of bonding may include: heating at least one of the insulator substrate and the donor semiconductor wafer; bringing the insulator substrate into direct or indirect contact with the exfoliation layer of the donor semiconductor wafer; and applying a voltage potential across the insulator substrate and the donor semiconductor wafer to induce the bond. The temperature of the insulator substrate and the semiconductor wafer may be elevated to within about 150 degrees C of the strain point of the insulator substrate. The temperatures of the insulator substrate and the semiconductor wafer may be elevated to different levels. The voltage potential across the insulator substrate and the semiconductor wafer may be between about 100 to 10000 volts. Stress may be induced by cooling the bonded insulator substrate, exfoliation layer, and donor semiconductor wafer such that a fracture occurs substantially at an ion-defect phase defining a boundary of the exfoliation layer within the donor semiconductor wafer. The heat and differential coefficients of thermal expansion, of the ion-defect phase, versus the surrounding wafer, cause the exfoliation layer to cleave at the ion-defect phase. The result is a thin film of semiconductor bonded to the insulator.

The at least one cleaved surface may include a first cleaved surface of the donor semiconductor wafer and a second cleaved surface of the exfoliation layer. With respect to the first cleaved surface associated with donor semiconductor wafer, the finishing process may include preparing the donor semiconductor wafer for reuse. With respect to the second cleaved surface associated with exfoliated layer, the finishing process may include completing the partially completed photovoltaic cell.

According to one or more preferred embodiment of the present invention, new solar cells may be based on single crystal Ge, Si or GaAs films on transparent glass -or glass ceramic substrates. In the case of GaAs-based cells, as an added advantage, a germanium layer may be present between the substrate and the single crystalline GaAs layer. The germanium layer may be doped in order to use the substrate as a bottom layer (i.e., back contact layer) of a multi-junction solar cell. The glass or glass ceramic substrates may be expansion matched to Ge, Si, GaAs or Ge/GaAs. The strongly adherent single crystal layer of Si, Ge, GaAs or Ge/GaAs film may be obtained on the glass or glass ceramic substrate via an anodic bonding process described in U.S. Patent Application No. 2004/0229444.

The process first involves hydrogen or hydrogen and helium implantation of the Ge, Si or GaAs wafer, and in the case of GaAs, possibly followed by deposition of a germanium film on the surface of the GaAs wafer. The Ge, Si or Ge-coated GaAs wafer is then bonded to the glass substrate, followed by separation of a thin film structure of Ge, Si, GaAs or GaAs/Ge. The SOG structure thus obtained may be polished to remove the damaged region and to expose the good quality single crystal layer of the semiconductor. This SOG structure may be used then as a template for subsequent epitaxial growth of multiple layers of Si, Ge, GaAS, GaInP₂, GaInAs, etc. to form desired solar cells. The glass, in addition to being expansion matched to the semiconductor layer also may have a strain point high enough to withstand subsequent deposition conditions.

Typical photovoltaic cell structures include a p-type—intrinsic—n-type (p-i-n), a metal-insulator-semiconductor (MIS), so-called “tandem” junction cells, multi-junction cells, and complex p-n multilayer structures, but the present invention is not limited to these structures. It is within the competency of persons of ordinary skill in the photovoltaics arts to create the partially completed photovoltaic cell on the donor semiconductor wafer according to desired product characteristics, such as single-junction versus multi-junction. Similarly, whether the partially completed photovoltaic cell is created before or after the ion implantation is a decision within the competency of persons of ordinary skill, taking into consideration a suitable ion penetration depth in the semiconductor material.

It is noted that the donor semiconductor wafer may be a part of structure that includes a substantially single-crystal donor semiconductor wafer and optionally includes an epitaxial semiconductor layer disposed on the donor semiconductor wafer. The exfoliation layer (e.g., the layer bonded to the insulator substrate -and separated from the donor semiconductor structure) may thus be formed substantially from the single-crystal donor semiconductor wafer material. Alternatively, the exfoliation layer may be formed substantially from the epitaxial semiconductor layer (and which may also include some of the single-crystal donor semiconductor wafer material).

The advantages of this invention are best understood after reading the detailed technical description, and in relation to existing SOI processes. Nonetheless, the primary advantages include: photovoltaic structure variation; thinner silicon films; more uniform silicon films with higher crystal quality; faster manufacturing throughput; improved manufacturing yield; reduced contamination; and scalability to large substrates. These benefits naturally combine to reduce costs.

Photovoltaic structures (PVS) may be varied insofar as complex photovoltaic structures may be made through high temperature processes on donor semiconductor wafers. The resultant high performance PVS then may be transferred to a low-cost glass substrate and completed, for instance, with deposition of remaining layers and any patterning required to complete the circuitry.

The present invention allows use of only the required thickness of semiconductor (around 10-30 microns for Si, and 1-3 microns for direct bandgap semiconductors such as GaAs). In contrast to the transfer of thicker silicon films to the insulator substrate that are then polished to remove the damaged surface, control of which is difficult for very thin films, little material is removed in the process as described in this invention, allowing thin silicon films to be transferred directly, with additional thickness deposited or grown thereafter.

Uniform films are very desirable. Again, because little material is removed in the process, the silicon film thickness uniformity is determined by the ion implant. This has been shown to be quite uniform, with a standard deviation of around 1 nm. In contrast, polishing typically results in a deviation in film thickness of 5% of the amount removed.

As demand continues to rise, faster throughput is critical. However, the polishing technologies identified for fabricating SiOG have process times on the order of tens of minutes, and the furnace anneals can be several hours. With more uniform films, the need in photovoltaic cells for polishing or furnace annealing is reduced.

Improving manufacturing yield is also important for waste and cost reduction. By avoiding the wire-saw kerf loss, material waste may be reduced significantly. Likewise, the expensive donor semiconductor wafer may be polished and reused multiple times. By using thin films, material consumption likewise may be reduced significantly. If polishing of the SOI structure is avoided, the overall manufacturing yield is expected to improve. This is particularly true if the polishing process has a low step yield, as anticipated. The process window is expected to be large because of the crystalline nature of the film, and therefore the yield is expected to be high.

Due to the sensitive nature of SOIs, contamination adversely may affect performance, so reducing contamination is highly desirable. With this in mind, avoiding the need for polishing with an abrasive slurry to reduce layer thickness reduces the potential for contamination. Furthermore, avoiding the need for a furnace anneal also avoids the diffusion of contaminants that may occur during a lengthy thermal anneal process. This may play an important consideration in the efficiency of the photovoltaic devices.

The process is scalable to large areas. This scalability potentially extends the product life as customer substrate size requirements increase. Solar panels are often large to maximize use of available space, so the larger photovoltaic cells become, the fewer photovoltaic cells are necessary to connect to create a large solar panel. In contrast, surface polishing and furnace annealing become increasing difficult for larger substrate sizes.

In particular, key advantages of preferred embodiments of the present invention include: 1) the use of low cost, expansion-matched glass or glass ceramic substrates, compared to other more expensive semiconductor substrates (such as silicon for a Ge layer and subsequent GaAs growth, as has been used previously) or thermally mismatched ceramic substrates described in the prior art; 2) the presence of the single crystal template layer of Si, Ge or multilayer GaAs/Ge on the glass substrate, which is used as a template to create lattice matched, very low defect semiconductor layers for the solar cells with high efficiencies, unlike polycrystalline templates used in prior art; 3) the transparency of the substrate allowing flexibility in module fabrication.

Other aspects, features, advantages, etc. will become apparent to one skilled in the art when the description of the invention herein is taken in conjunction with the accompanying drawings.

### BRIEF DESCRIPTION OF THE DRAWINGS

For the purposes of illustrating the various aspects of the invention, wherein like numerals indicate like elements, there are shown in the drawings simplified forms that are presently preferred, it being understood, however, that the invention is not limited by or to the precise arrangements and instrumentalities shown, but rather only by the issued claims. The drawings are not to scale, nor are the aspects of the drawings to scale relative to each other.

FIGS. 1, 2 and 3 are block diagrams illustrating, respectively, a single-junction, a dual-junction, and a triple-junction photovoltaic structure and the progression of the historical efficiencies of each.

FIGS. 4, 5 and 6 are block diagrams, each illustrating a photovoltaic structure in accordance with one or more embodiments of the present invention.

FIGS. 7, 8 and 9 are flow diagrams illustrating process steps that may be carried out to produce a photovoltaic SOI structure in accordance with one or more embodiments of the present invention.

FIGS. 10-18 are block diagrams illustrating intermediate and near-final structures formed using the processes in accordance with one or more embodiments of the present invention.

FIGS. 19 and 20 depict a flow diagram and block diagram, respectively, illustrating process steps and assemblies used in a system for formation of photovoltaic structures.

FIG. 21 depicts a simplified multijunction photovoltaic structure according to one or more preferred embodiments of the present invention.

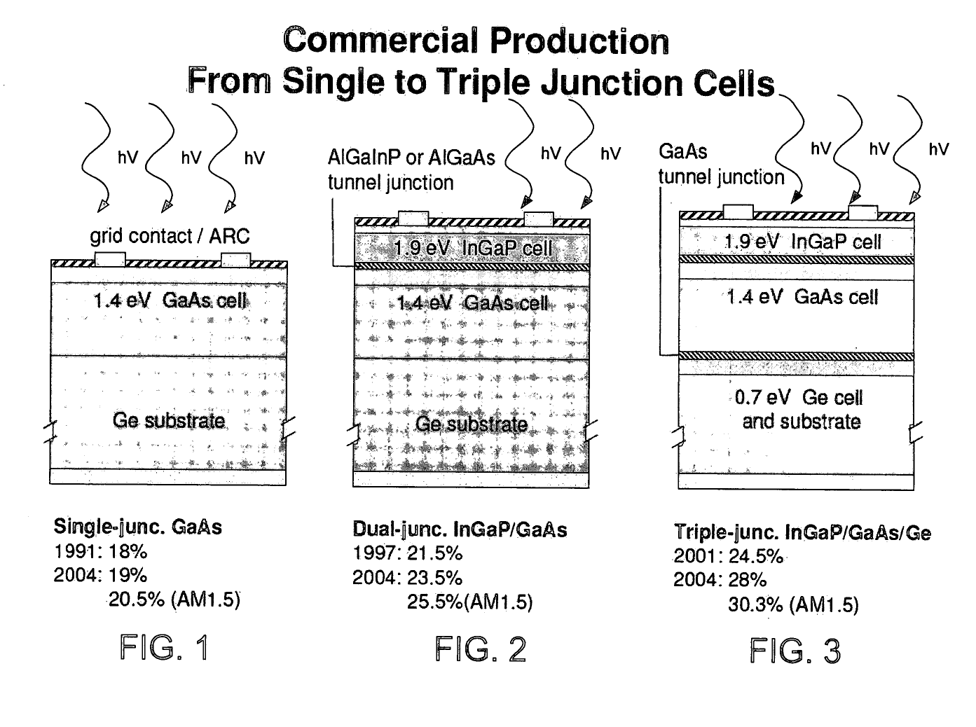

### DETAILED DESCRIPTION OF THE PRESENT INVENTION

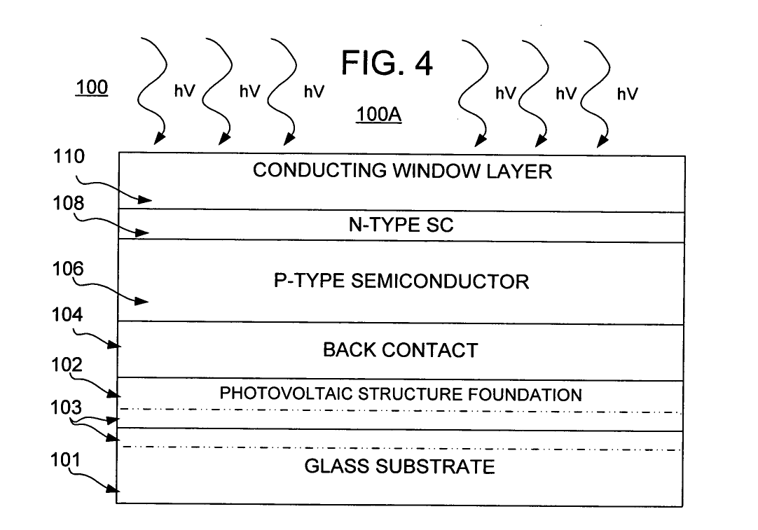

Referring to FIGS. 4, 5 and 6, occasionally referred to collectively as FIGS. 4-6, there are shown PVS variations 100A, 100B and 100C, respectively, of photovoltaic SOI structure 100 in accordance with one or more embodiments of the present invention. Photovoltaic SOI structure 100 may be referred to as a PV SOI structure 100, or simply PVS 100. With respect to the figures, the SOI structure 100 is exemplified as an SiOG structure. The SiOG structure 100 may include an insulator substrate 101 made of glass, a photovoltaic structure foundation 102 (FIG. 4), ion migration zones 103, a back contact layer 104, a p-type semiconductor layer 106, an n-type semiconductor layer 108, and a conducting window layer 110. The SiOG structure 100 has suitable uses in connection with photovoltaic devices.

The conducting window layer 110 is an electrically conductive layer of material that is acting as an ohmic contact. The conducting window layer may be translucent, transparent or semi-transparent. An exemplary material would be indium tin oxide, a material that typically is formed by reactive sputtering of an In—Sn target in an oxidative atmosphere. An alternative to indium tin oxide may include, for instance, aluminium-doped zinc oxide, boron-doped zinc oxide, or even carbon nanotubes. Indium tin oxide (ITO, or tin-doped indium oxide) is a mixture of indium(III) oxide (In₂O₃) and tin(IV) oxide (SnO₂), typically may be 90% In₂O₃, 10% SnO₂ by weight. It is transparent and colorless in thin layers. In bulk form, it is yellowish to grey. Indium tin oxide's main feature is the combination of electrical conductivity and optical transparency. However, a compromise has to be reached during film deposition, as high concentration of charge carriers will increase the material's conductivity, but decrease its transparency. Thin films of indium tin oxide are most commonly deposited on surfaces by electron beam evaporation, physical vapor deposition, or a range of sputtering techniques.

The semiconductor material of the layers 106 and 108 may be in the form of a substantially single-crystal material. The term “substantially” is used in describing the layers 106, 108 to take account of the fact that semiconductor materials normally contain at least some internal or surface defects either inherently or purposely added, such as lattice defects or grain boundaries. The term substantially also reflects the fact that certain dopants may distort or otherwise affect the crystal structure of the semiconductor material. In particular, p-type semiconductor layer 106 includes a p-type doping agent, whereas n-type semiconductor layer 108 includes an n-type doping agent. Note that the p-type layer 106 is thicker than the n-type layer 108 in all cases where it is desired that the majority of the electron hole pairs are created in the p-type layer 106.

For the purposes of discussion, it is assumed that the semiconductor layers 106, 108 are formed from silicon, unless stated otherwise. It is understood, however, that the semiconductor material may be a silicon-based semiconductor or any other type of semiconductor, such as the III-V, II-IV, etc., classes of semiconductors. Examples of these materials include: silicon (Si), germanium-doped silicon (SiGe), silicon carbide (SiC), germanium (Ge), gallium arsenide (GaAs), gallium phosphide (GaP), and indium phosphide (InP).

The back contact layer 104 may be a conductive layer, such as a conductive metal-based or metal oxide-based layer. The back contact layer is an ohmic contact, i.e., a region on a semiconductor device that has been prepared so that the current-voltage (I-V) curve of the device is linear and symmetric. The back contact material may be chosen for its thermal robustness in contact with Si. For instance, back contact layer 104 may be film based on aluminum or a silicide, such as or titanium disilicide, tungsten disilicide or nickel silicide, an example of which is discussed below. A silicide-polysilicon combination has better electrical properties than polysilicon alone and yet does not melt in subsequent processing.

The back contact layer 104 may be created, for example, by deposition, such as LPE, CVD or PECVD. Mesotaxy or epitaxy may be used also. Whereas as epitaxy is the growth of a matching phase on the surface of a substrate, mesotaxy is the growth of a crystallographically matching phase underneath the surface of the host crystal. In this process, ions are implanted at a high enough energy and dose into a material to create a layer of a second phase, and the temperature is controlled so that the crystal structure of the target is not destroyed. The crystal orientation of the layer can be engineered to match that of the target, even though the exact crystal structure and lattice constant may be very different. For example, after the implantation of nickel ions into a silicon wafer, a layer of nickel silicide can be grown in which the crystal orientation of the silicide matches that of the silicon.

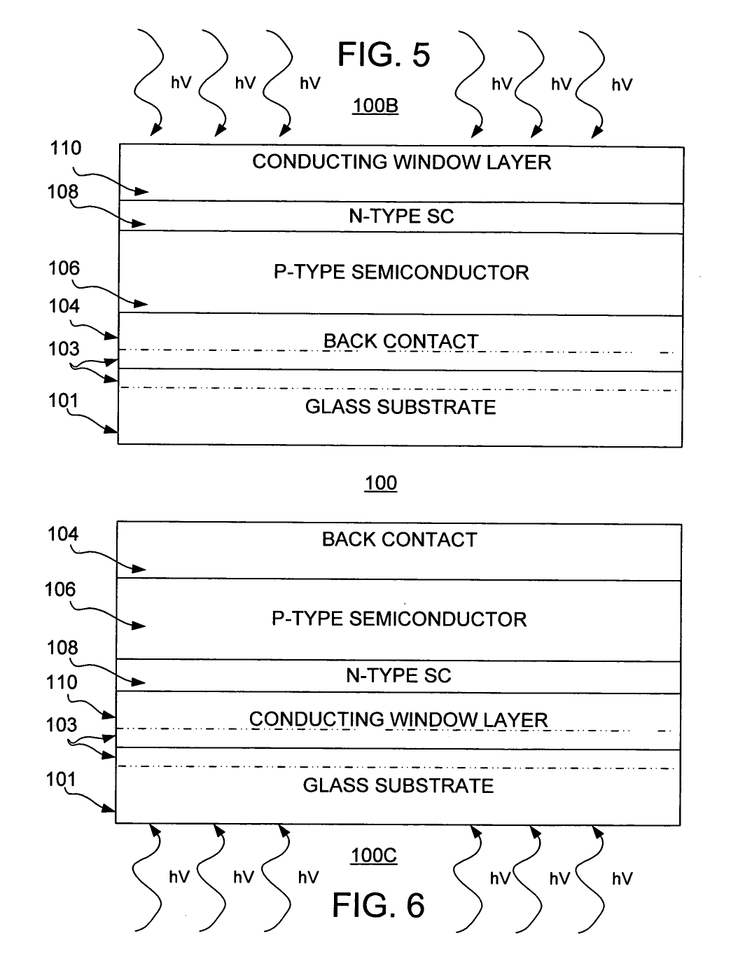

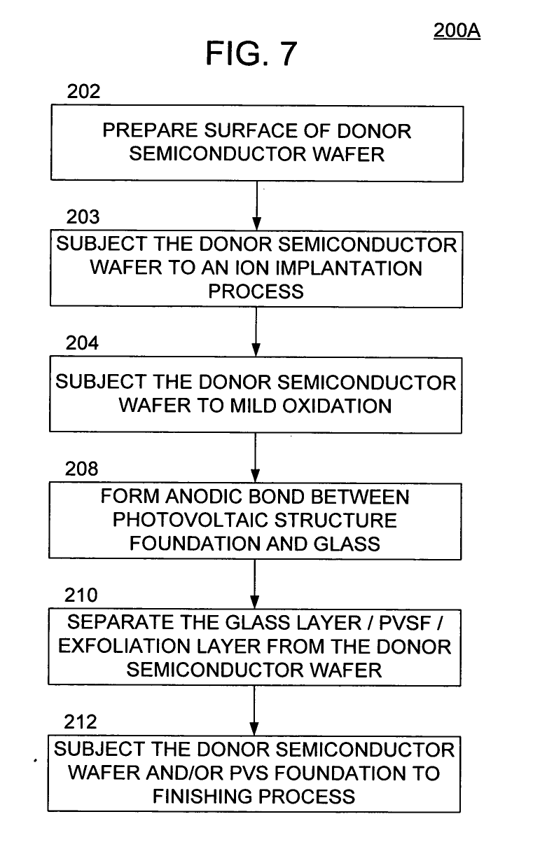

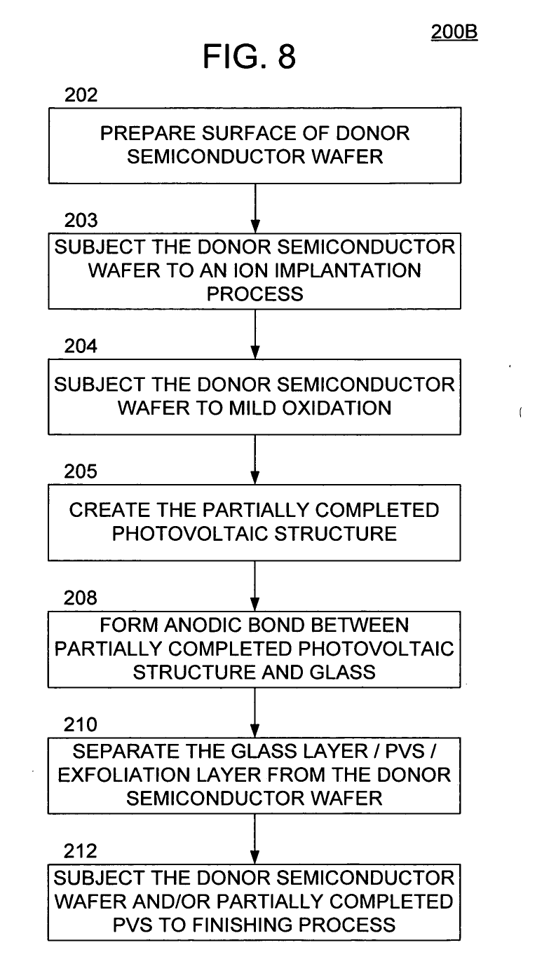

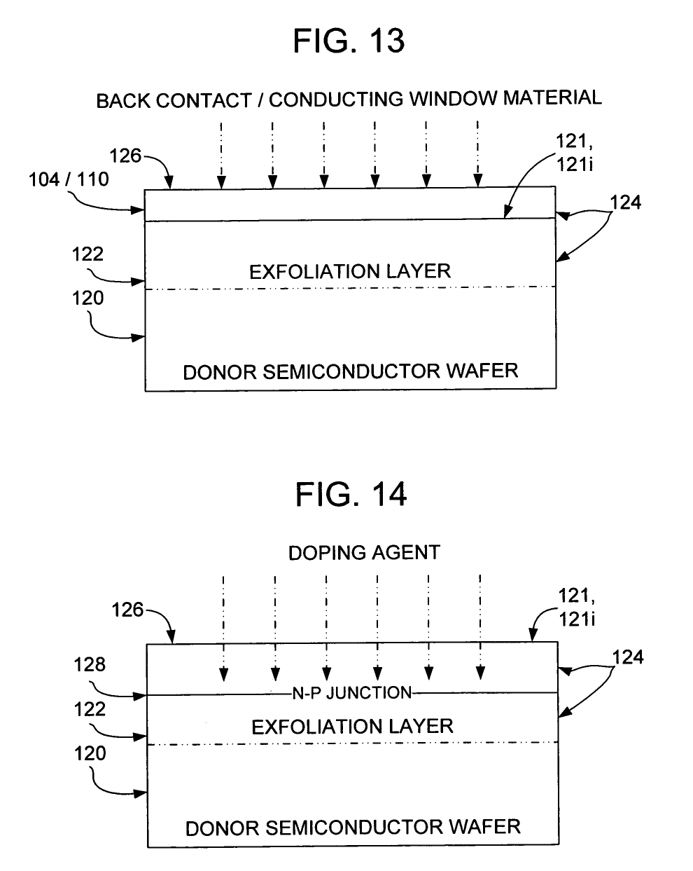

Use of epitaxy or mesotaxy to form back contact layer 104 may be thought of as a conceptual interface between the structure 100A described FIG. 4 and the structures 100B and 100C described in FIGS. 5 and 6, insofar as the exfoliation layer 122, discussed in FIGS. 7-9 and 11, may include an epitaxial or mesotaxial layer, forming the back contact 104, and the semiconductor layer above it. Whereas the semiconductor layer alone may serve as a photovoltaic structure foundation (PVSF) 102, in FIG. 4, the combination of the semiconductor layer and back contact layer 104 may be considered a partially completed PVS 124, introduced in FIGS. 8 and 13. Hence, forming back contact layer 104 using epitaxy or mesotaxy or ion implantation before anodic bonding (step 208) creates a partially completed PVS 124 that is transferred to the substrate 101 as in processes 200B and 200C, whereas transferring a PVSF 102 and then forming back contact layer 104 using epitaxy or mesotaxy or ion implantation after exfoliation separation (step 210) follows process 200A. Likewise, the back contact layer 104 may be formed by heavy doping of PVSF 102 after exfoliation separation. Such heavy doping can typically be carried out by ion implantation.

Moreover, if the back contact layer 104 is deposited on top of PVSF 102 after exfoliation separation (step 210), a PVS 100 of variation 100A may result. Alternatively, if PVSF 102 is doped, before or after mesotaxy, as a p-type semiconductor and back contact layer 104 is formed by mesotaxy, a PVS 100 similar to variation 100A or 100B may result. If the depth of the mesotaxial growth of the back contact layer 104 is within the middle of PVSF 102, a layer of PVSF 102 may remain underneath the back contact layer 104, as in variation 100A. If the depth of the mesotaxial growth of the back contact layer 104 reaches the bonding surface 126 of PVSF 102, little to none of the layer of PVSF 102 may remain underneath the back contact layer 104, as in variation 100B.

Insofar as the conductive layer is formed on or in the exfoliation layer 122, whether formed by epitaxy, mesotaxy, ion implantation, doping, vapor transport, vapor deposition, etc., the conductive layer will be integral to the exfoliation layer 122. If the conductive layer is formed on or in the exfoliation layer 122 before the exfoliation layer 122 is bonded to the insulator substrate 101, the conductive layer will be proximate to the insulator substrate 101 when the exfoliation layer 122 is bonded to the substrate 101. In other words, the conductive layer will have been formed near the side of the exfoliation layer 122 that faces the insulator substrate, such that, for example, the resulting conductive layer may be between the insulator substrate and the exfoliation layer. If the exfoliation layer 122 is bonded to the insulator substrate 101 first and then the conductive layer is formed on or in the exfoliation layer 122 thereafter, the conductive layer will be on or near the side of the exfoliation layer 122 opposite the insulator substrate 101 and thus distal to the insulator substrate 101. Likewise, any photovoltaic device layers formed in, on or above the exfoliation layer 122 after the exfoliation layer 122 has been bonded to the insulator substrate 101 will be distal to the insulator substrate 101.

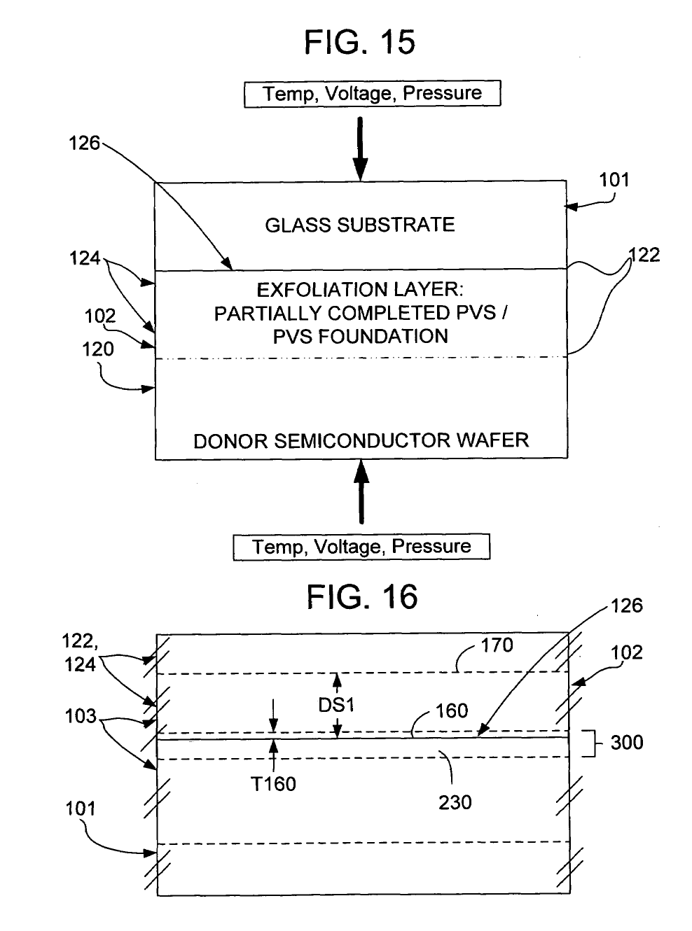

As will be discussed in more detail in reference to FIGS. 15-17, an ion migration zone 103 forms on either side of an anodic bond between the insulator substrate 101 and the layer bonded to the insulator substrate 101; i.e., PVS foundation 102, in variation 100A; back contact 104, in variation 100B; or conducting window layer 110, in variation 100C. The ion migration zones 103 result from the anodic bonding process described in FIG. 15. These ion migration zones 103 have not been present in prior art photovoltaic structures.

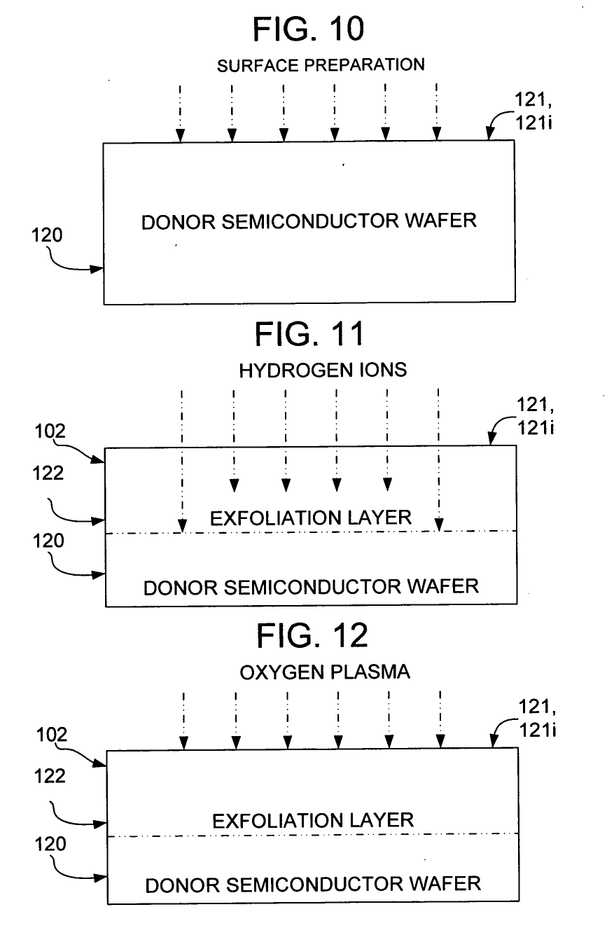

In contrast to variations 100B and 100C in FIGS. 5 and 6, variation 100A in FIG. 4 includes a PV structure foundation 102. Photovoltaic structure foundation 102 may arise when the exfoliation layer 122 is transferred to the insulator substrate 101 in the absence of any additional layer(s) that would amount to a partially completed PVS 124 (PCPVS). In essence, the exfoliation layer 122 may be thought to become the PVSF 102 upon bonding to insulator substrate 101. As such, PVSF 102 preferably may comprise a substantially single crystal semiconductor layer, as it comes from donor wafer 120 introduced in FIGS. 7 and 10.

The insulator substrate 101, here a glass substrate 101, may be formed from an oxide glass or an oxide glass-ceramic. Although not required, the embodiments described herein may include an oxide glass or glass-ceramic exhibiting a strain point of less than about 1,000 degrees C. As is conventional in the glass making art, the strain point is the temperature at which the glass or glass-ceramic has a viscosity of 10^{14.6} poise (10^{13.6} Pa·s). As between oxide glasses and oxide glass-ceramics, the glasses may have the advantage of being simpler to manufacture, thus making them more widely available and less expensive.

By way of example, the glass substrate 101 may be formed from glass substrates containing alkaline-earth ions, such as, substrates made of CORNING INCORPORATED GLASS COMPOSITION NO. 1737 or CORNING INCORPORATED GLASS COMPOSITION NO. EAGLE²⁰⁰⁰™. These glass materials have other uses, in particular, for example, the production of liquid crystal displays.

The glass substrate may have a thickness in the range of about 0.1 mm to about 10 mm, such as in the range of about 0.5 mm to about 3 mm. For some SOI structures, insulating layers having a thickness greater than or equal to about I micron (i.e., 0.001 mm or 1000 nm) are desirable, e.g., to avoid parasitic capacitive effects which arise when standard SOI structures having a silicon/silicon dioxide/silicon configuration are operated at high frequencies. In the past, such thicknesses have been difficult to achieve. In accordance with the present invention, an SOI structure having an insulating layer thicker than about 1 micron is readily achieved by simply using a glass substrate 101 having a thickness that is greater than or equal to about 1 micron. A lower limit on the thickness of the glass substrate 101 may be about 1 micron, i.e., 1000 nm.

In general, the glass substrate 101 should be thick enough to support the semiconductor layer 106, 108 through the bonding process steps, as well as subsequent processing performed on the photovoltaic SiOG structure 100. Although there is no theoretical upper limit on the thickness of the glass substrate 101, a thickness beyond that needed for the support function or that desired for the ultimate photovoltaic SiOG structure 100 might not be advantageous since the greater the thickness of the glass substrate 101, the more difficult it will be to accomplish at least some of the process steps in forming the photovoltaic SiOG structure 100.

The oxide glass or oxide glass-ceramic substrate 101 may be silica-based. Thus, the mole percent of SiO₂ in the oxide glass or oxide glass-ceramic may be greater than 30 mole percent and may be greater than 40 mole percent. In the case of glass-ceramics, the crystalline phase can be mullite, cordierite, anorthite, spinel, or other crystalline phases known in the art for glass-ceramics. Non-silica-based glasses and glass-ceramics may be used in the practice of one or more embodiments of the invention, but are generally less advantageous because of their higher cost and/or inferior performance characteristics.

Similarly, for some applications, e.g., for SOI structures employing semiconductor materials that are not silicon-based, glass substrates which are not oxide based, e.g., non-oxide glasses, may be desirable, but are generally not advantageous because of their higher cost. As will be discussed in more detail below, in one or more embodiments, the glass or glass-ceramic substrate 101 is designed to match a coefficient of thermal expansion (CTE) of one or more semiconductor materials (e.g., silicon, germanium, etc.) of the layer(s) (potentially 102, 104, 106, 108, or 110) that is (are) bonded thereto, directly or indirectly. The CTE match ensures desirable mechanical properties during heating cycles of the deposition process.

For photovoltaic applications, the glass or glass-ceramic 101 may be transparent in the visible, near UV, and/or IR: wavelength ranges, e.g., the glass or glass ceramic 101 may be transparent in the 350 nm to 2 micron wavelength range. Having transparent, or at least translucent, glass is important in particular in variation 100C, where the light enters the insulator substrate 101 before reaching the rest of PV structure 100C. However, in variations 100A and 100B, the light does not enter the insulator substrate 101, so it is largely irrelevant whether the insulator substrate 101 is translucent, let alone transparent, in which case the insulator substrate 101 is chosen based on other criteria, inter alia CTE, not the least of which is cost.

Although the glass substrate 101 may be composed of a single glass or glass-ceramic layer, laminated structures may be used if desired. When laminated structures are used, the layer of the laminate closest to the layer bonded thereto (e.g., 102, 104 or 110) may have the properties discussed herein for a glass substrate 101 composed of a single glass or glass-ceramic. Layers farther from the bonded layer may also have those properties, but may have relaxed properties because they do not directly interact with the bonded layer. In the latter case, the glass substrate 101 is considered to have ended when the properties specified for a glass substrate 101 are no longer satisfied.

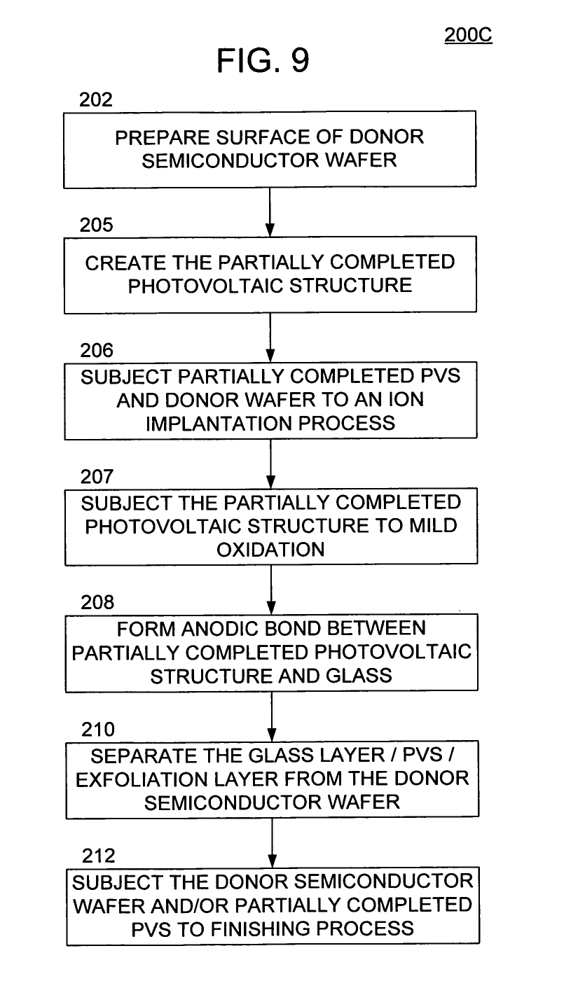

Referring to FIGS. 7, 8 and 9, occasionally referred to collectively as FIGS. 7-9, process steps are illustrated that may be carried out in order to produce the PV structure 100 in accordance with one or more embodiments of the present invention. Process 200A is depicted in FIG. 7, process 200B is depicted in FIG. 8, and process 200C is depicted in FIG. 9. FIGS. 10-18 illustrate intermediate and near-final structures that may be formed in carrying out the processes of FIGS. 7, 8 and 9.

At action 202 of FIGS. 7-10, a prepared donor surface 121 of a donor semiconductor wafer 120 is prepared, such as by polishing, cleaning, etc. to produce a relatively flat and uniform prepared donor surface 121 suitable for bonding to a subsequent layer of the PVS. The prepared donor surface 121 will form the underside of the PV structure foundation 102 or semiconductor layer 106, 108. For the purposes of discussion, the semiconductor wafer 120 may be a doped (n-type or p-type) substantially single-crystal Si wafer, although as discussed above any other suitable semiconductor materal may be employed.

At either action 203, for processes 200A and 200B, or action 206, for process 200C, also shown in FIG. 11, an exfoliation layer 122 is created by subjecting an ion impantation surface 121i, i.e., the prepared donor surface 121, and any layer created on prepared donor surface 121, to one or more ion implantation processes to create a weakened region below the prepared donor surface 121 of the donor semiconductor wafer 120. Although the embodiments of the present invention are not limited to any particular method of forming the exfoliation layer 122, one suitable method dictates that the prepared donor surface 121 of the donor semiconductor wafer 120 may be subject to a hydrogen ion implantation process to at least initiate the creation of the exfoliation layer 122 in the donor semiconductor wafer 120.

The implantation energy may be adjusted using conventional techniques to achieve an approximate thickness of the exfoliation layer 122. By way of example, hydrogen ion implantation may be employed, although other ions or multiples thereof may be employed, such as boron+hydrogen, helium+hydrogen, or other ions known in the literature for exfoliation. Again, any other known or hereinafter developed technique suitable for forming the exfoliation layer 122 may be employed without departing from the spirit and scope of the present invention.

Depending on the parameters of the PV SOI structure 100, the number and thickness of layers on top of the prepared donor surface 121, and the potential use of any intermediate preparation step, such as CMP or FA, the exfoliation layer 122 may be made as thick or thin as desired and/or as feasible. If various design constraints require the exfoliation layer 122 to be thicker than desired, such as for use in microelectronics, a known method of mass removal, such as CMP or polishing, may be used to reduce the thickness of the layer 122 after it is exfoliated in action 210. However, using a mass removal step adds time and expense to the overall manufacturing process and may not be necessary for PVS 100. For instance, in variation 100A, the PVSF 102 layer may not need to be thin or thick; preferably, PVSF 102 is thick enough to serve as a stable foundation for later finishing processes, but otherwise thin to conserve materials, and hence money.

The opposite issue is more likely to arise with PV structure 100, namely that the exfoliation layer may be too thin. In variations 100B and 100C, a thick layer of Si is desirable for a PVS 100 because a thicker layer of Si will absorb more light and increase its efficiency.- The energy needed to create a desirably thick exfoliation layer may exceed available equipment parameters, and hence additional Si may be deposited or grown epitaxially after the exfoliation layer 122 is created. The additional Si may be added to the exfoliation layer 122 before or after it is transferred to the glass substrate 101. If added before, the Si addition becomes part of a creation of a partially completed PVS 124, whereas if added after, the Si addition becomes part of a finishing process. Similarly, semiconductor layers will be added to PVS 100A after PVSF 102 and back contact 104 are on substrate 101.

At either action 204, for processes 200A and 200B, or action 207, for process 200C, also shown in FIG. 12, the ion implantation surface 121i, i.e., the prepared donor surface 121, and any layer created on prepared donor surface 121, on donor semiconductor wafer 120 may be treated to reduce, for example, the hydrogen ion concentration on the ion implantation surface 121i. For example, the donor semiconductor wafer 120 may be washed and cleaned, and the bonding surface 126 of the exfoliation layer 122 may be subjected to mild oxidation. The mild oxidation treatments may include treatment in oxygen plasma, ozone treatments, treatment with hydrogen peroxide, hydrogen peroxide and ammonia, hydrogen peroxide and an acid or a combination of these processes. It is expected that during these treatments hydrogen-terminated surface groups oxidize to hydroxyl groups, which in turn also makes the surface of the bonding surface 126 hydrophilic. The treatment may be carried out at room temperature for the oxygen plasma and at temperature between 25-150° C. for the ammonia or acid treatments.

Action 205 of FIGS. 8 and 9, also shown in FIGS. 13 and 14, involves creating a partially completed PVS 124 on the donor semiconductor wafer 120. The partially completed PVS 120 may be created either after the exfoliation layer 122 is created, as in process 200B, or before the exfoliation layer 122 is created, as in process 200C. After both the exfoliation layer 122 and the partially completed PVS 124 are created, though, the exfoliation layer actually forms part of the partially completed PVS 124. An exposed surface of the partially completed PVS 124 will be a bonding surface 126 for bonding to the glass insulator substrate 101 in action 208.

With reference to FIGS. 13 and 14, occasionally referred to collectively as FIGS. 13-14, the donor semiconductor wafer 120 may be processed as part of the creation of a partially-completed PVS 124. FIGS. 13-14 depicts the exfoliation layer 122 as already having been formed on the prepared donor surface 121 of the donor semiconductor wafer 120, when further steps are taken in the creation of the partially completed PVS 124. Many different actions may be taken in creating the partially completed PVS 124. For instance, creation of the partially completed PVS 124 may include, as shown in FIG. 13, addition of the back contact layer 104, as in variation 100B, or addition of the conducting window layer 110, as in variation 110B, or as shown in FIG. 14, use of an intermediary doping step.

FIG. 13 depicts the addition, according to one or more embodiments of the present invention, of either the back contact layer 104, as in variation 100B, or the conducting window layer 110, as in variation 100C. On a high level, these two processes are similar enough to may be depicted using one block diagram. While a simplified deposition process is depicted, such as CVD or PECVD, the diagram is meant to represent any possible process, such as epitaxy and mesotaxy, as discussed above. It is preferred that the back contact 104, or conducting window layer 110, respectively, be deposited on the partially completed PVS 124, rather than directly on the glass substrate 101, prior to bonding the partially completed PVS and the glass substrate 101, insofar as the anodic bonding process of action 208 appears to work better in this sequence. Another benefit of depositing one of these onto the partially completed PVS 124 while attached to the donor semiconductor wafer 120 would be the relaxation of process constraints required to deposit these layers directly onto the glass substrate 101, which may be more sensitive to extreme conditions.

FIG. 14 depicts the ion implantation surface 121i of exfoliation layer 122 being doped, creating a subsurface n-p junction 128. Depending on whether variation 100B or 100C is desired, for example, semiconductor layers 106, 108 may be made from a doped Si boule that receives an opposite doping on its surface. In an exemplary embodiment of variation 100B, an n-type doped donor semiconductor layer 120 may be doped on its surface with a p-type doping agent, creating a subsurface n-p junction. Conversely, in an exemplary embodiment of variation 100C, a p-type doped donor semiconductor layer 120 may be doped on its surface with an n-type doping agent, creating a subsurface n-p junction.

At action 208, in FIGS. 7-9 and 15, the glass substrate 101 may be bonded to the bonding surface 126 of the exfoliation layer 122/PVSF 102/partially completed PVS 124. A suitable bonding process is described in U.S. Patent Application No. 2004/0229444, the entire disclosure of which is hereby incorporated by reference. Portions of this process, known as anodic bonding, electrolysis, bonding by means of electrolysis, and/or forming an anodic bond by electrolysis, are discussed below. In the anodic bonding/electrolysis process, appropriate surface cleaning of the glass substrate 101 (and the bonding surface 126/exfoliation layer 122 if not done already) may be carried out. Thereafter, the intermediate structures are brought into direct or indirect contact to achieve the arrangement schematically illustrated in FIGS. 15-16.

Prior to or after the contact, the structure(s) comprising the donor semiconductor wafer 120, the exfoliation layer 122/PVSF 102/partially completed PVS 124, and the glass substrate 101 are heated under a differential temperature gradient. The glass substrate 101 may be heated to a higher temperature than the donor semiconductor wafer 120 and exfoliation layer 122/PVSF 102/partially completed PVS 124. By way of example, the temperature difference between the glass substrate 101 and the donor semiconductor wafer 120 (and the exfoliation later 122/PVSF 102/partially completed PVS 124) is at least 1 degree C, although the difference may be as high as about 100 to about 150 degrees C. This temperature differential is desirable for a glass having a coefficient of thermal expansion (CTE) matched to that of the donor semiconductor wafer 120 (such as matched to the CTE of silicon) since it facilitates later separation of the exfoliation layer 122 from the semiconductor wafer 120 due to thermal stresses. The glass substrate 101 and the donor semiconductor wafer 120 may be taken to a temperature within about 150 degrees C of the strain point of the glass substrate 101.

Once the temperature differential between the glass substrate 101 and the donor semiconductor wafer 120 is stabilized, mechanical pressure is applied to the intermediate assembly. The pressure range may be between about 1 to about 50 psi. Application of higher pressures, e.g., pressures above 100 psi, might cause breakage of the glass substrate 101. The appropriate pressure may be determined in light of the manufacturing parameters, such as materials being used, and their thicknesses.

Next, a voltage is applied across the intermediate assembly, for example with the donor semiconductor wafer 120 at the positive electrode and the glass substrate 101 the negative electrode. The application of the-voltage potential causes alkali or alkaline earth ions in the glass substrate 101 to move away from the semiconductor/glass interface further into the glass substrate 101. This accomplishes two functions: (i) an alkali or alkaline earth ion free interface is created; and (ii) the glass substrate 101 becomes very reactive and bonds strongly to the exfoliation layer 122 of the donor semiconductor wafer 120.

At action 210, of FIGS. 7-9 and 15, after the intermediate assembly is held under the above conditions for some time (e.g., approximately 1 hour or less), the voltage is removed and the intermediate assembly is allowed to cool to room temperature. The donor semiconductor wafer 120 and the glass substrate 101 are then separated, which may include some peeling if they have not already become completely free, to obtain a glass substrate 101 with the relatively thin exfoliation layer 122/PVSF 102/partially completed PVS 124 formed of the semiconductor material of the donor semiconductor layer 120 bonded thereto. The separation may be accomplished via fracture of the ion implantation zone due to thermal stresses. Alternatively or in addition, mechanical stresses, such as water jet or laser cutting, or chemical etching may be used to facilitate the separation.

Referring to FIG. 16, the ion migration zone 103 mentioned in reference to FIGS. 4-6 is shown in greater detail. The structural details pertain particularly to the anodic bond region at the interface of the glass substrate 101 and the layer just above it, either PVSF 102 in FIG. 4, back contact 104 in FIG. 5, or conducting window layer 110 in FIG. 6, of the exfoliation layer 122. The bonding process (action 208) transforms the interface between the exfoliation layer 122 and the glass substrate 101 into an interface region 300. The interface region 300 preferably comprises a hybrid region 160 and a depletion region 230. The interface region 300 may also include one or more positive ion pile-up regions in the vicinity of the distal edge of the depletion region 230.

The hybrid region 160 is of enhanced oxygen concentration of thickness T160. When bonding the conducting window layer 110, for instance, this hybrid region 160 may be enhanced by beginning with a composition stoichiometrically depleted of oxygen to enhance oxygen transfer from the glass substrate 101. This thickness may be defined in terms of a reference concentration for oxygen at a reference surface 170 within the exfoliation layer 122/PVSF 102/partially completed PVS 124. The reference surface 170 is substantially parallel to the bonding surface between the glass substrate 101 and the exfoliation layer 122/PVSF 102/partially completed PVS 124 and is separated from that surface by a distance DS1. Using the reference surface 170, the thickness T160 of the hybrid region 160 will typically satisfy the relationship:

T160≦200 nm,

where T160 is the distance between bonding surface 126 and a surface which is: (i) substantially parallel to bonding surface 126, and (ii) is the surface farthest from bonding surface 126 for which the following relationship is satisfied:

CO(x)-CO/Ref≧50 percent, 0≦x≦T160,

where CO(x) is the concentration of oxygen as a function of distance x from the bonding surface 126, CO/Ref is the concentration of oxygen at the above reference surface 170, and CO(x) and CO/Ref are in atomic percent.

Typically, T160 will be substantially smaller than 200 nanometers, e.g., on the order of about 50 to about 100 nanometers. It should be noted that CO/Ref will typically be zero, so that the above relationship will in most cases reduce to:

CO(x)≧50 percent, 0≦x≦T160.

In connection with the depletion region 230, the oxide glass or oxide glass-ceramic substrate 101 preferably comprises at least some positive ions that move in the direction of the applied electric field, i.e., away from the bonding surface 126 and into the glass substrate 101. Alkali ions, e.g., Li⁺¹, Na⁺¹, and/or K⁺¹ ions, are suitable positive ions for this purpose because they generally have higher mobility rates than other types of positive ions typically incorporated in oxide glasses and oxide glass-ceramics, e.g., alkaline-earth ions.

However, oxide glasses and oxide glass-ceramics having positive ions other than alkali ions, e.g., oxide glasses and oxide glass-ceramics having only alkaline-earth ions, can be used in the practice of the invention. The concentration of the alkali and alkaline-earth ions can vary over a wide range, representative concentrations being between 0.1 and 40 wt. % on an oxide basis. Preferred alkali and alkaline-earth ion concentrations are 0.1 to 10 wt. % on an oxide basis in the case of alkali ions. and 0-25 wt. % on an oxide basis in the case of alkaline-earth ions.

The electric field applied in the bonding step (action 208) moves the positive ions (cations) further into the glass substrate 101 forming the depletion region 230. The formation of the depletion region 230 is especially desirable when the oxide glass or oxide glass-ceramic contains alkali ions, since such ions are known to interfere with the operation of semiconductor devices. Alkaline-earth ions, e.g., Mg⁺², Ca⁺², Sr⁺², and/or Ba⁺², can also interfere with the operation of semiconductor devices and thus the depletion region also preferably has reduced concentrations of these ions.

It has been found that the depletion region 230 once formed is stable over time even if the PV structure 100 is heated to an elevated temperature comparable to, or even to some extent higher than, that used in the bonding process. Having been formed at an elevated temperature, the depletion region 230 is especially stable at the normal operating and formation temperatures of PV structures. These considerations ensure that alkali and alkaline-earth ions will not diffuse back from the oxide glass or oxide glass-ceramic 101 into the semiconductor material 104 during use or further device processing, which is an important benefit derived from using an electric field as part of the bonding process.

As with selecting the operating parameters to achieve a strong bond, the operating parameters needed to achieve a depletion region 230 of a desired width and a desired reduced positive ion concentration for all of the positive ions of concern can be readily determined by persons skilled in the art from the present disclosure. When present, the depletion region 230 is a characteristic feature of a PV structure 100 produced in accordance with one or more embodiments of the present invention.

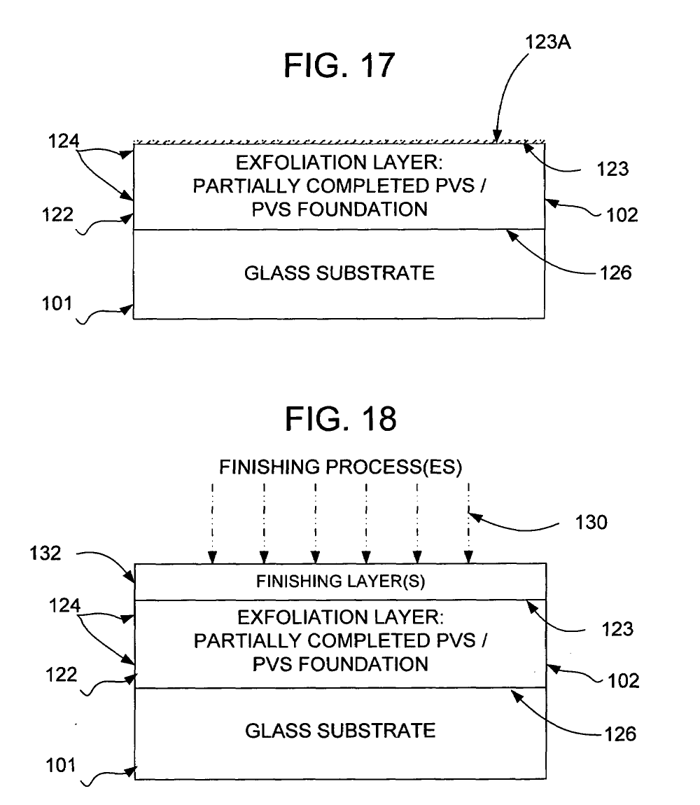

As illustrated in FIG. 17, after separation, the resulting structure may include the glass substrate 101 and the exfoliation layer 122 of semiconductor material bonded thereto. The cleaved surface 123 of the SOI structure just after exfoliation may exhibit excessive surface roughness 123A (depicted abstractly in FIG. 17), possible excessive silicon layer thickness (more likely for microelectronic applications), and implantation damage of the silicon layer (e.g., due to hydrogen-ions and the formation of an amorphized silicon layer).

At action 212, in FIGS. 7-9 and 18, the donor semiconductor wafer 120, PVSF 102, and/or partially completed PVS 124 may be subjected to one or more finishing process(es) 130. The finishing process 130 may include, for example, one or more subprocesses. For instance, a finishing process 130 may include various scribing steps needed to create the topography of PVS variations 100B and 100C. Such scribing steps, well known in the art, may be done before, after, or in conjunction with other finishing processes 130.

Another finishing process 130 may include augmenting the semiconductor thickness of the exfoliation layer 122. In the case of variation 100A, semiconductor material may be added, for example, before mesotaxial growth of a back contact layer 104. It is desired in certain embodiments that the final combined thickness of the semiconductor layers 106 and 108 should be, for example, more than 10 microns (i.e., 10000 nm) and less than about 30 microns. Therefore, an appropriately thick exfoliation layer 122 should be created and augmented with an additional semiconductor layer 132 (e.g., of Si) until the desired thickness is created. Augmentation with an additional Si layer 132 may include a doping step as well. Historically, the amorphized silicon layer has been on the order of about 50-150 nm in thickness, and depending on the implantation energy and implantation time, the thickness of the exfoliation layer 122 has been on the order of about 500 nm. As with microelectronic SOI structures, however, a thinner exfoliation layer 122 may be created for the PVSF 102, with the amorphized silicon layer necessarily being thinner as well, with more semiconductor material added in the finishing processes.

Also according to action 212, the cleaved surface 123 may subject to post-cleaving processing which may include subjecting the cleaved surface 123 to a polishing or annealing process to reduce roughness 123A. Moreover, in order to achieve the exemplary embodiment of variation 100B, the finishing process may include application of the conducting window layer 110, such as deposition of indium tin oxide. Conversely, to achieve the exemplary embodiment of variation 100C, the finishing process may include application of the back contact layer 104, a conductive metal-based or metal oxide-based layer, such as an aluminum-based film deposited by LPE, CVD or PECVD. As discussed above, back contact layer 104 also may be formed by epitaxial or mesotaxial growth, such as of nickel silicide.

To the extent that the partially completed PVS 124 has more of the features of the intended final product, fewer finishing processes are necessary. By contrast, insofar as the formation of PVSF 102 on insulator substrate 101 alone does not distinguish the substrate 101-PVSF 102 combination as a photovoltaic structure over any other semiconductor-on-insulator structure of U.S. Patent Application No. 2004/0229444, several PVS-specific finishing processes are necessary. However, having a substantially single crystal layer as the photovoltaic structure foundation 102 relaxes the parameters within which to operate and expands the scope of options and outcomes available from which to choose, in proceeding with the finishing processes.

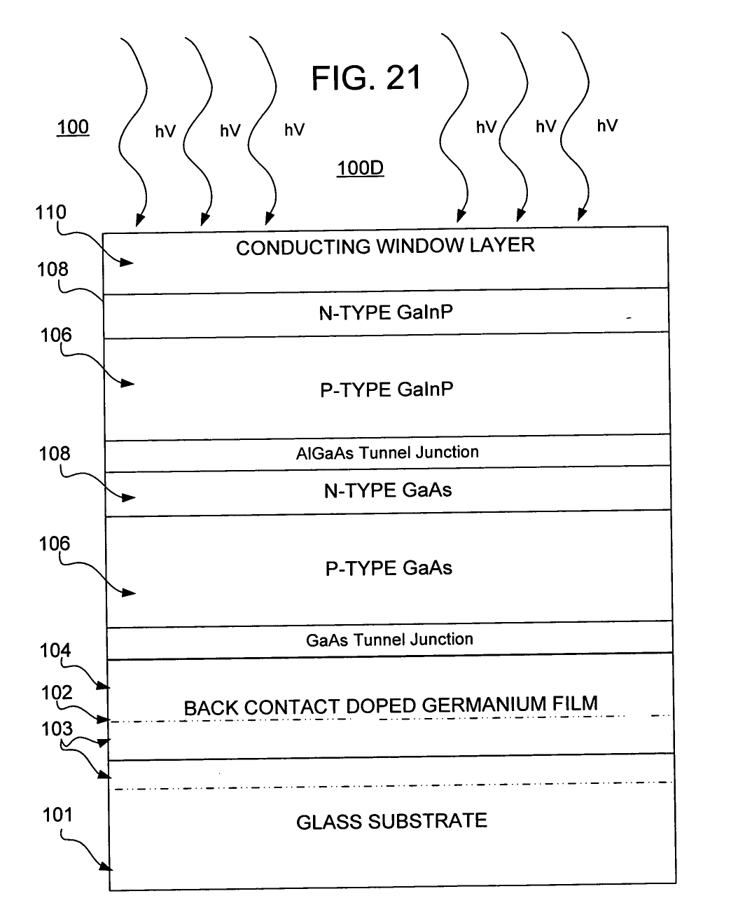

In particular, formation of the PVSF 102 or the partially completed PVS 124 allows for greater flexibility in the creation of advanced, multi-junction PVS devices. For example, building on a PVSF 102 of crystal-Si, a manufacturer may exploit the different specific heat capacities of crystal-Si versus GaAs, Ge, and GaInP₂ to create various multi-junction layers of GaAs, Ge and GaInP₂. Optionally, as the preferred embodiments of FIG. 21 describe, the PVSF 102 may comprise Ge, or GaAs, or the PCPVS 124 may comprise a doped Ge/GaAs layer.

Alternative embodiments of the invention will now be described with reference to the aforementioned SiOG processes and further details. For example, a result of separating the exfoliation layer 122 from the donor semiconductor wafer 120 may produce a first cleaved surface of the donor semiconductor wafer 120 and a second cleaved surface 123 of the exfoliation layer 122. As previously discussed, the finishing process 130 may be applied to the second cleaved surface 123 of the exfoliation layer 122. Additionally or alternatively, the finishing process 130 may be applied to the first cleaved surface of the donor semiconductor wafer 120 (using one or more of the techniques described above), such as polishing.

In another embodiment of the present invention, the donor semiconductor wafer 120 may be part of a donor structure, including a substantially single-crystal donor semiconductor wafer 120, and an epitaxial semiconductor layer disposed on the donor semiconductor wafer 120. (Details of an epitaxially grown semiconductor layer in an SOI context may be found in co-pending U.S. patent application Ser. No. 11/159,889, filed Jun. 23, 2005, the entire disclosure of which is incorporated herein by reference.) The exfoliation layer 122, therefore, may be formed-substantially from the epitaxial semiconductor layer (and may also include some of the single-crystal donor semiconductor material from the wafer 120). Thus, the aforementioned finishing process may be applied to the cleaved surface 123 of an exfoliation layer 122 formed substantially of epitaxial semiconductor material and/or a combination of epitaxial semiconductor material and single-crystal semiconductor material.

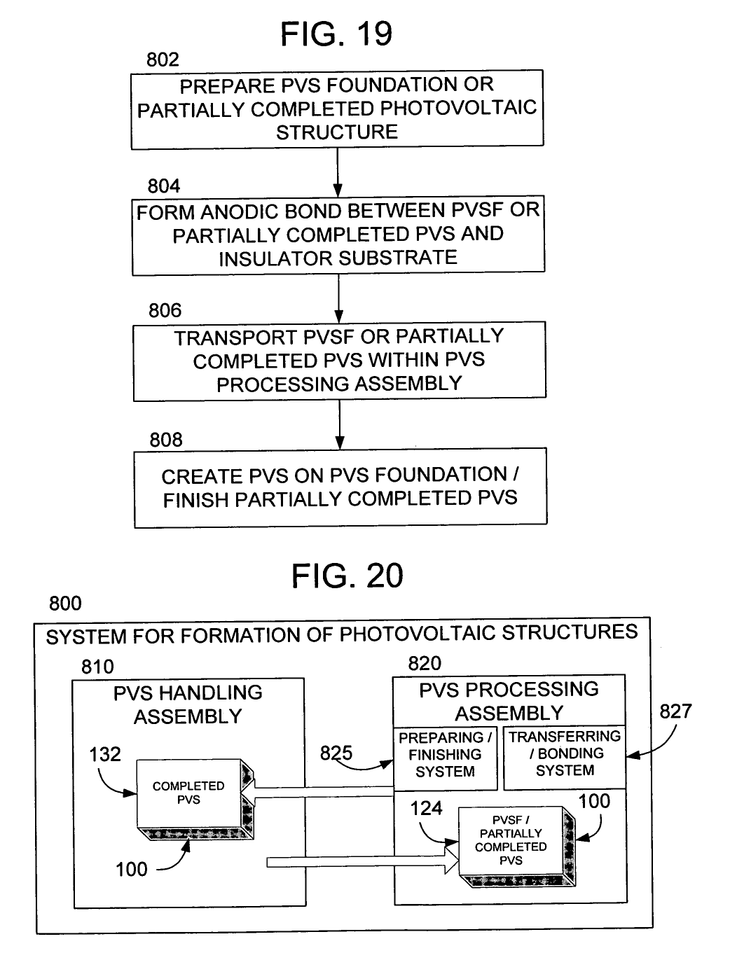

As depicted in FIG. 19, showing exemplary formation steps 802-808, and FIG. 20, showing an exemplary system 800, the photovoltaic cell creation process could be automated, moreover, in a system 800 for the formation of photovoltaic structures 100. The system 800 could include a PVS handling assembly 810, which handles the PV structures 100 for processing, and a photovoltaic processing assembly 820. The photovoltaic processing assembly 820 would include various subsystems, such as a preparing or finishing system 825 and a transferring or bonding system 827, used in manufacturing PV structures 100 being handled by the PV semiconductor-on-insulator handling assembly 810.

For example, when the exfoliation layer 122 is prepared, comprising either the PVSF 102 or partially completed PV structure 124 (step 802), the handling assembly could transport and position the PV structures 100 in need of completion within the PVS processing assembly 820 to permit anodic bonding (step 804) to occur. Further transportation and positioning (step 806) of the substrate 101, bonded to PVSF 102 or partially completed PVS 124, within the PVS processing assembly 820 may allow additional actions 210 and 212 of exfoliating and finishing, respectively, to occur (step 808).

Referring to FIG. 21, a simplified multifunction variation 100D of PVS 100 is depicted according to one or more preferred embodiments. Multijunction PVS 100D may bear a general resemblance to the PVS of FIG. 3, but with important exceptions, such as the substitution of a glass substrate for the crystal-Ge wafer substrate, with an exfoliated crystal-Ge film on top of the glass substrate. A p-type germanium or a GaAs wafer 500 microns thick with a resistivity of 0.01-0.04 Ohm-Cm may be implanted with hydrogen at 100 Kev and a dosage of 8×10¹⁶. The wafer then may be cleaned by chemical means and subjected to oxygen plasma treatment to oxidize the surface groups. Following cleaning, the GaAs wafer may be inserted into the-deposition chamber and coated with a layer of doped or undoped Ge film, the thickness depending on the device design. Deposition of germanium onto the GaAs wafer maybe accomplished with a variety of techniques including plasma enhanced chemical vapor deposition, ion beam assisted sputter deposition, evaporation or chemical vapor phase epitaxy. Doping (p-type) of the Ge layers can be accomplished with As or P. An alkali-aluminoborosilicate glass wafer with thermal expansion matched to germanium and thickness of 1 mm then may be washed with standard cleaning techniques, such as with a detergent and distilled water followed by a dilute acid wash to clean the surface. The two wafers then may be brought into contact and placed in a bonding system. A voltage of 1000V may be applied across the wafers at 450C and 400C, the temperatures of the glass and germanium wafer or Ge-coated GaAs wafer, respectively, for 20 minutes before cooling down and removing the applied voltage. A thin film of germanium or a multilayer of GaAs/Ge bonded to the glass may be separated from the mother wafer, with very strong bonding to the glass being achieved.

The glass wafer with the germanium or GaAs/Ge film optionally then may be polished, annealed or healed to remove the damaged germanium or GaAs top layer and a good quality layer surface. This wafer may be used as a substrate to grow epitaxial structures to form the solar cell. Examples of materials may include GaAs, GaInP/GaAs, GaₓIn_{y}P/Ga_{c}, In_{d}As/Ge and others known in the art. Various processes may be utilized to deposit the epitaxial films including CVST (closed space vapor transport), MOCVD (metallo-organic chemical vapor deposition), MBE (molecular beam epitaxy) and others known in the art. A number of surface passivating window layers such as wide bandgap epilayers of AlGaAs, InGaP or ZnSe may be employed as well as other encapsulating or passivation layers and surface treatments may be used to complete the cell.

The ohmic contacts may be applied in varying configurations, depending on the device design, but the basic requirement is that the produced current flow from one contact to the next contact to allow for a completed electric circuit, the circuit being completed once the two electrodes leading from the device are coupled with a load. As such, the back contact layer need not be the outermost layer relative to the semiconductor layers, as depicted in FIG. 6. For instance, the back contact 104 may rest on top, rather than underneath, semiconductor layer 106, if spaced appropriately to create a proper circuit and electrical flow configuration.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

We claim:

1. A photovoltaic device, comprising:
an insulator structure;
an exfoliation layer; and
a conductive layer integral to the exfoliation layer and proximate to the insulator structure; and
a bond bonding the insulator structure to the conductive layer and the exfoliation layer,
wherein the exfoliation layer comprises a substantially single-crystal exfoliation layer of a substantially single-crystal donor semiconductor wafer.

2. The photovoltaic device of claim 1, wherein the bond is an anodic bond formed by electrolysis.

3. The photovoltaic device of claim 2, wherein the anodic bond comprises an interface region.

4. The photovoltaic device of claim 3, wherein the interface region comprises a hybrid region and a depletion region.

5. The photovoltaic device of claim 1, further comprising:
a first ion migration zone in the insulator; and
a second ion migration zone across the conductive layer and the exfoliation layer.

6. The photovoltaic device of claim 1, wherein the conductive layer comprises a metal-based material or a metal-oxide based material.

7. The photovoltaic device of claim 1, wherein the exfoliation layer comprises a doped semiconductor layer and the conductive layer comprises a back contact layer or a conducting window layer.

8. The photovoltaic device of claim 7, wherein the doped semiconductor layer comprises an n-type semiconductor layer, a p-type semiconductor layer, or a semiconductor junction layer having n-type and p-type doped regions.

9. The photovoltaic device of claim 7, wherein:
the back contact layer comprises aluminum, titanium, nickel, tungsten, indium, molybdenum, gold, platinum, palladium, gallium, tin, antimony, silver, germanium, or a silicide; and
the conducting window layer comprises tin-doped indium oxide, aluminum-doped zinc oxide, boron-doped zinc oxide, or carbon nanotubes.

10. The photovoltaic device of claim 1, further comprising a plurality of photovoltaic device layers created in or on the exfoliation layer and distal to the insulator substrate.

11. The photovoltaic device of claim 10, wherein the plurality of photovoltaic device layers includes at least one semiconductive layer, at least one conductive layer, and at least one passivating layer.

12. The photovoltaic device of claim 10, wherein at least one of the plurality of photovoltaic device layers comprises an epitaxially grown crystalline layer.

13. The photovoltaic device of claim 1, further comprising at least one additional photovoltaic device layer integral to the exfoliation layer and proximate to the insulator substrate.

14. A photovoltaic device, comprising:
an insulator structure;
an exfoliation layer proximate to the insulator structure;
an anodic bond bonding the insulator structure and the exfoliation layer; and
a plurality of photovoltaic device layers distal to the insulator substrate and in or on the exfoliation layer;
wherein the exfoliation layer comprises a substantially single-crystal exfoliation layer of a substantially single-crystal donor semiconductor wafer.

15. The photovoltaic device of claim 14, further comprising:
a first ion migration-zone in the insulator; and
a second ion migration zone in the exfoliation layer.

16. The photovoltaic device of claim 14, wherein the anodic bond comprises an interface region.

17. The photovoltaic device of claim 16, wherein the interface region comprises a hybrid region and a depletion region.

18. The photovoltaic device of claim 14, wherein the plurality of photovoltaic device layers includes a semiconductive layer and a conductive layer.

19. The photovoltaic device of claim 18, wherein the plurality of photovoltaic device layers further includes at least one more semiconductive layer, at least one more conductive layer, and at least one passivating layer.

20. The photovoltaic device of claim 18, wherein the conductive layer comprises a metal-based material or a metal-oxide based material.

21. The photovoltaic device of claim 14, wherein the plurality of photovoltaic device layers includes a doped semiconductor layer, a back contact layer and a conducting window layer.

22. The photovoltaic device of claim 21, wherein the doped semiconductor layer comprises an n-type semiconductor layer, a p-type semiconductor layer, or a semiconductor junction layer having n-type and p-type doped regions.

23. The photovoltaic device of claim 21, wherein:
the back contact layer comprises aluminum, titanium, nickel, tungsten, indium, molybdenum, gold, platinum, palladium, gallium, tin, antimony, silver, germanium, or a silicide; and
the conducting window layer comprises tin-doped indium oxide, aluminum-doped zinc oxide, boron-doped zinc oxide, or carbon nanotubes.

24. The photovoltaic device of claim 14, wherein at least one of the plurality of photovoltaic device layers comprises an epitaxially grown crystalline layer.
